(19) United States
(12) Patent Application Publication
(10) Pub. No.: US 2008/0024165 A1
(43) Pub. Date: Jan. 31, 2008

(54) Configurable embedded multi-port memory

(76) Inventors: Raminda Udaya Madurawe, Sunnyvale, CA (US); Thomas Henry White, Santa Clara, CA (US); Peter Ramyalal Suaris, Danville, CA (US)

Correspondence Address: RAMINDA U. MADURAWE, 882 LOUISE DRIVE, SUNNYVALE, CA, 94087, US

(21) Appl. No.: 11/494,001

(22) Filed: Jul. 28, 2006

(51) Int. Cl. H03K 19/177

(52) U.S. Cl. 326/41

(57) ABSTRACT

Programmable routing structures to couple physical memory nodes to logical memory nodes in embedded multi-port memory FPGA's are disclosed. In a first embodiment, a plurality of physical domain nodes couples a plurality of variable node sets in a logical read domain, wherein a configuration element activates one of the sets and selects a fixed input or an address signal to decode the data read. In a second embodiment, a plurality of physical domain nodes couples a plurality of variable node sets in a logical write domain, wherein a configuration element activates one of the sets and couples a fixed input or an address signal to an enable signal of a driver device to decode the data written. A third embodiment provide logical read and logical write functions for a single port in a multi-port physical memory array, wherein the logical read data width and the logical write data width can be independently configured, and wherein the read and write functions share common address lines.

This application is related to U.S. Pat. No. 6,747,478, U.S. Pat. No. 7,064,018 which is a continuation of now abandoned application Ser. No. 10/267,484 filed on Oct. 8, 2002, and application Ser. No. 10/267,483 filed on Oct. 8, 2002; all of which list as inventor Mr. R. U. Madurawe, the contents of which are incorporated herein by reference.

This application is further related to U.S. Pat. Nos. 6,828,689, 6,856,030, 6,849,958, 6,998,722, all of which list as inventor Mr. R. U. Madurawe, the contents of which are incorporated herein by reference.

### BACKGROUND

The present invention relates to embedded memory in programmable logic applications. More specifically, it relates to concatenating embedded physical memory blocks to build logical read domain and logical write domain memory that comprises configurable data width and depth.

Traditionally, application specific integrated circuit (ASIC) devices have been used in the integrated circuit (IC) industry to reduce cost, enhance performance or meet space constraints. The generic class of ASIC devices falls under a variety of sub classes such as Custom ASIC, Standard cell ASIC, Gate Array and Field Programmable Gate Array (FPGA) where the degree of user allowed customization varies. In this disclosure, the term ASIC is used to identify Custom and Standard Cell ICs where the designer has to incur the cost of a full fabrication mask set. The term FPGA denotes a pre-fabricated programmable IC with no fabrication mask costs, and Gate Array denotes an IC with partial mask costs to the designer. FPGA's include all field Programmable Logic Devices (PLD), and Gate Arrays include all mask Programmable Array Devices further including Structured ASIC and Structured Array devices.

The design and fabrication of ASICs can be time consuming and expensive. The customization involves a lengthy design cycle during the product definition phase and high Non Recurring Engineering (NRE) costs during manufacturing phase. In the event of finding a logic error in the custom or semi-custom ASIC during final test phase, the design and fabrication cycle has to be repeated. Such lengthy correction cycles further aggravate the time to market and engineering cost. As a result, ASICs serve only specific applications and are custom built for high volume and low cost. The high cost of masks and unpredictable device life time shipment volumes have caused ASIC design starts to fall precipitously in the IC industry. ASICs offer no device for immediate design verification, no interactive design adjustment capability, and require a full mask set for fabrication.

Gate Array customizes pre-defined modular logic blocks at a reduced NRE cost by designing the module connections with a software tool similar to that in ASIC. The Gate Array has an array of mask programmable functional modules fabricated on a semiconductor substrate. To interconnect these modules to a user specification, multiple layers of wires are used during design synthesis. The level of customization may be limited to a single metal layer, or single via layer, or multiple metal layers, or multiple metals and via layers. The goal is to reduce the customization cost to the user, and provide the customized product faster. As a result, the customizable layers are designed to be the top most metal and via layers of a semiconductor fabrication process. This is an inconvenient location to customize wires as the customized transistors are located at the substrate level of the Silicon, and all possible connection choices must be accommodated at the top layers. Structured ASICs fall into larger module Gate Arrays, and provide varying degrees of complexity in the structured cell and the custom interconnection. The absence of Silicon for design verification and design optimization results in multiple spins and lengthy iterations to the end user. As the Gate Array evaluation phase is similar to that of an ASIC, the advantage is in a reduced NRE cost for fewer customization layers, tools and labor, and shorter time to receive the finished product. The end IC is more expensive compared to an ASIC, and less flexible compared to an FPGA.

In recent years there has been a move away from custom, semi-custom and Gate Array ICs toward field programmable devices whose function is determined not when the integrated circuit is fabricated, but by an end user “in the field” prior to use. Off the shelf FPGA products greatly simplify the design cycle and are fully customized by the user. These products offer user-friendly software to fit custom logic into the device through field programmability, and the capability to tweak and optimize designs to improve Silicon performance. Provision of this programmability is expensive in terms of Silicon real estate, but reduces design cycle time, time to solution (TTS) and upfront NRE cost to the designer. FPGAs offer the advantages of low NRE costs, fast turnaround (designs can be placed and routed on an FPGA in typically a few minutes), and low risk since designs can be easily amended late in the product design cycle. It is only for high volume production runs that there is a cost benefit in using the other two approaches. Compared to FPGA, an ASIC and Gate Array both have mask level hard-wired interconnect identified during chip design phase. An ASIC has no multiple logic choices, and both ASIC and most Gate Arrays have no configuration memory to customize logic. This is a large chip area and cost saving for these approaches. Smaller die sizes also lead to better performance. A full custom ASIC has customized logic functions which take less gate counts compared to generic Gate Arrays and FPGA configurations for the same functions. Thus, an ASIC is significantly smaller, faster, cheaper and more reliable than an equivalent gate-count FPGA. A Gate Array is also smaller, faster and cheaper compared to an equivalent FPGA. The trade-off is between time-to-market (FPGA advantage) versus low cost and better reliability (ASIC advantage). A Gate Array falls in the middle with an improvement in the ASIC NRE cost at a moderate penalty to product cost and performance. The cost of Silicon real estate for programmability provided by the FPGA compared to ASIC and Gate Array contribute to a significant portion of the extra cost the user has to bear for customer re-configurability of logic functions.

A Gate Array was disclosed by Wahlstrom in U.S. Pat. No. 3,473,160. In that, in FIG. 1, a mask programmable device comprising a plurality of pre-arranged gate array cells and a plurality of interconnects for routing signals is presented. Additional improvements to Gate Array and FPGA architectures are further discussed in US. Patents issued to: Carter U.S. Pat. Nos. 4,642,487, 4,706,216, Freemann U.S. Pat. Nos. 4,870,302, 5,488,316, 5,343,406, ElGamal et al. U.S. Pat. No. 4,873,459, Hartman U.S. Pat. No. 4,609,986, Turner U.S. Pat. Nos. 4,761,768, 6,781,409, Trimberger et al. U.S. Pat. No. 5,844,422, Cliff et al. U.S. Pat. No. 6,134,173, Wittig et al. U.S. Pat. No. 6,208,163, Or-Bach U.S. Pat. No. 6,331,789, US 2001/003428, Mendel U.S. Pat. No. 6,275,065, Lee et al. 2001/0048320, Young et al. U.S. Pat. No. 6,448,808, Sueyoshi et al. 2003/0001615, Agrawal et al. 2002/0186044, Sugibayashi et al. U.S. Pat. No. 6,515,511 and Pugh et al. 2003/0085733. These patents disclose programmable MUX and LUT structures to build logic cells that are user configurable. In all cases a programmable routing block is used to provide inputs and outputs for these logic cells, while the logic cell is further configured to perform a specific logic function. The routing-block is mask-programmed in Gate Array and Structured ASIC devices, and field-programmed in FPGA devices.

New Timing Exact 3D-FPGA's & 3D-ASIC's were disclosed in application Ser. No. 10/267,483 and U.S. Pat. Nos. 6,747,478, 7,030,651, 6,992,503, 7,064,018 and 7,064,579; the contents of which are incorporated herein by reference. These disclosures provide a significant cost reduction to 2D FPGA devices by integrating portions of circuits in a 3-dimentional construction, and ensuing architectural innovations. When the unit cost of the 3D-FPGA is similar to a Gate Array, and within twice that of an ASIC, the preferred user option is the 3D-FPGA due to availability, ease of use, lower NRE costs and Time-to-Market benefits.

In an FPGA, a complex logic design is broken down to smaller logic blocks and programmed into logic blocks provided in the FPGA. Logic blocks contain multiple smaller logic elements. Logic elements facilitate sequential and combinational logic design implementations. Combinational logic has no memory and outputs reflect a function solely of present input states. Sequential logic is implemented by inserting memory in the form of a flip-flop into the logic path to store past history. Current FPGA architectures include transistor pairs, NAND or OR gates, multiplexers, look-up-tables (LUT) and AND-OR structures in a basic logic element. In a PLD the basic logic element is labeled a macro-cell. Hereafter the terminology logic element will include both logic elements and macro-cells.

For sequential logic designs, the logic element may also include flip-flops. A MUX based exemplary logic element described in Ref-1 (Seals & Whapshott) is shown in FIG. 1A. The logic element has a built in D-flip-flop 105 for sequential logic implementation. In addition, elements 101, 102 and 103 are 2:1 MUX's controlled by one input signal for each MUX. Input S1 feeds into 101 and 102, while inputs S1 and S2 feed into OR gate 104, and the output from OR gate feeds into 103. Element 105 is the D-Flip-Flop receiving Preset, Clear and Clock signals. One may very easily represent the programmable MUX structure in FIG. 1A as a 2-input LUT; where A, B, C & D are LUT values, and S1, (S2+S3) are LUT inputs. Ignoring the global Preset & Clear signals, eight inputs feed into the logic element, and one output leaves the logic element. All 2-input, all 3-input and some 4-input variable functions are realized in the logic element and latched to the D-Flip-Flop. Inputs and outputs for the Logic Element or Logic Block are selected from the programmable Routing Matrix. An exemplary routing matrix containing logic elements as described in Ref-1 is shown in FIG. 1B. Each logic element 112 is as shown in FIG. 1A. The 8 inputs and 1 output from logic element 112 in FIG. 1B are routed to 22 horizontal and 12 vertical interconnect wires that have programmable via connections 110. These connections 110 may be anti-fuses or pass-gate transistors controlled by SRAM memory elements. The user selects how the wires are connected during the design phase, and programs the connections either at mask-level (Gate Array) or in the field (FPGA). FPGA architectures for various commercially available FPGA devices are discussed in Ref-1 (Seals & Whapshott) and Ref-2 (Sharma).

To address various user memory needs incurred in designs, most commercial Gate Arrays and FPGA's provide embedded memory blocks. The most common embedded user memory is SRAM. The dual-port SRAM is disclosed by Reinert in U.S. Pat. No. 4,125,877. In that, in FIG. 3, a cross-coupled latch is provided with a first and second port for independent access to the data stored in the latch. Address and data lines allow parallel access to stored data. Use of CMOS Dual-Port SRAM in a Gate Array master-slice is disclosed by Bowers in U.S. Pat. No. 4,541,076. In that, FIGS. 1A & 1B show the master-slice comprising a plurality of metal programmable gate array cells, a dual-port memory block, and a plurality of interconnects for routing signals. Multiple master-slices offer higher gate array & SRAM density. Compared to a Gate Array, in an FPGA there are two types of memory—configuration memory to store customization data and embedded memory blocks to store user data. In this disclosure the term “memory circuits” include both configuration and embedded memory. An FPGA (3200DX family) with multiple embedded Dual-Port memory blocks was commercially shipped by Actel Corporation in Q3, 1995 (Ref-3 “EETimes” August 1995). In that, up to ten 256 bit Dual-Port memory blocks are inter-dispersed within field programmable logic regions inside an interconnect grid (Ref-4 “Application Notes” September-1997, Ref-5 “Data Sheet V3.0” February 2001, Ref-2 “Sharma” pp 127-128). Both ports in dual-port memory blocks can be configured as 32×8 or 64×4 bit configurations, and multiple memory blocks can be combined to build ×16, ×32 type variable width or 128, 256 bit type variable depth memory banks. This ability for a user to configure 256-bit fixed physical memory block into a wide variety of varying logical memory blocks significantly enhance the value of embedded memory in FPGA's. Prior art memory integration Architectures are disclosed in great depth in Ref. 6 (Wilton “PhD Thesis” 1997), and in publications Ref-7 (Ngai “CICC95” May 1995), Ref-8 (Wilton “FPGA97” February 1997), Ref-9 (Wilton “FPGA95” 1995) and Ref-10 (Wilton “CICC96” May 1996). One example of prior art embedded memory in an FPGA from Ref-6 (their FIG. 6.6) is shown in FIG. 2A. In that, a plurality of programmable blocks (such as 201) and a plurality of memory blocks (such as 205) are inter-dispersed in a programmable interconnect grid (such as 203). The logic block 201 has inputs/outputs 202 that couple to the interconnect grid. Vertical and horizontal interconnect couple to each other at routing block 204. Memory block 205 has inputs/outputs such as address lines and data lines that couple to interconnect grid at the interconnect block 206. A detailed view of the interconnect block 206 shown in ref. 6 (their FIG. 6.7) is shown in FIG. 2B. In that, programmable switches 252 allow a selection of vertical & horizontal interconnects (such as 251) in the FPGA fabric to couple to address & data lines (such as 253) to memory block 205. For multi-port memory, all address and data wires can be represented by the bundle of wires 253. A subsequent disclosure by Reddy in U.S. Pat. No. 6,052,327 (Provisional Application 60/062,966 filed Oct. 14, 1997) claims prior-art benefits of dual-port memory in an FPGA (claim-13), and variable depth and width write and read ports (claim-1).

A modification of single-port SRAM in LUT elements to dual-port SRAM is proposed for user memory in Freeman U.S. Pat. No. 5,343,406, Kean U.S. Pat. No. 5,801,547 and Lucent ORCA FPGA (Ref-7, “CICC Conference paper”, 1995). Such schemes have two major draw-backs: (i) enormously “memory” area inefficient when used as memory blocks and (ii) un-necessarily penalizes LUT logic as the 2^{nd} port consumes real estate that is scarce in FPGA's. Other methods to inter-disperse small RAM blocks within Logic blocks are disclosed in U.S. Pat. No. 6,249,143 & U.S. Pat. No. 6,870,398. These offer various solutions as how different depths & widths of data can be constructed by concatenating the small fixed size RAM blocks. More elaborated block RAM integration in FPGA's are provided in U.S. Pat. No. 5,715,197, U.S. Pat. No. 5,977,791, U.S. Pat. No. 6,127,843, U.S. Pat. No. 6,211,695, U.S. Pat. No. 6,467,017, U.S. Pat. No. 6,486,702 and U.S. Pat. No. 7,038,952. Specifically in U.S. Pat. No. 5,715,197, a specialized MUX circuit and a specialized decoder are used to map data from fixed data-width port in SRAM block to a variable data-width port. In that (FIGS. 2-4) to translate 4 bits from the physical RAM block to READ & WRITE ports, 8*4:1 MUX's, 12 2-input gates, 2-configuration bits & 2 address-signals are utilized. The specialized decoder generates common select signals to all the MUX's, said decoder utilizing configuration and address inputs. Such a scheme has two major draw backs. A first is the high decoder gate counts as the select signals are derived by address signals plus configuration bit outputs. For the 4-bit translation, 2-input standard decoder has bulged to a 4-input specialized decoder. The second is that both READ & WRITE ports share common select signals from the decoder, and lack independent data width configuration. A routing structure that utilizes fewer gates to implement the width configurability, and further comprises independent READ and WRITE data/width configurability within the same port is highly desirable.

A new 3D SRAM memory structure is disclosed in U.S. Pat. Nos. 6,828,689, 6,856,030, 6,849,958 and 6,998,722; the contents of which were incorporated-by-reference. These can be constructed as multi-port SRAM blocks, wherein the SRAM cell area is significantly reduced over conventional 2D-SRAM blocks. Such memory offers area reduction and access time improvement. These advantages would greatly enhance Embedded Memory value to the user within 2D-FPGA and 3D-FPGA devices. Furthermore, 3D-FPGA comprising 3D-embedded-memory structures provide architectural enhancements over the 2D-FPGA. Area efficient methods to independently configure the data width & depth for read and write functions within a common port in multi-port memory blocks are needed for these 3D-FPFA devices. Furthermore, the logical implementations of these physical hard-ware structures utilizing software tools must comprise easy to use Silicon hard-ware components.

### SUMMARY

In one aspect, an embedded memory block in an FPGA comprises a 3D inverter comprising a monolithic thin-film transistor.

Implementations of the above aspect may include one or more of the following. A semiconductor integrated circuit comprises an array of programmable modules. Each module may use one or more LUT or MUX based logic elements. A programmable interconnect structure may be used to interconnect these programmable modules in an FPGA device. One or more embedded memory blocks may also use the same interconnect structure. A logic design comprising memory blocks may be specified by the user in VHDL or Verilog design input language and synthesized to a gate-level netlist description. This synthesized netlist may be ported into logic and memory blocks and connected by the routing block in the FPGA. The memory block may comprise SRAM cells, each SRAM cell comprising a back-to-back inverter. One strong inverter may be constructed in a semiconductor substrate layer, and one weak inverter may be constructed in thin-film transistors deposited monolithically above the substrate. The SRAM cell may be smaller in area, the ensuing bit line and word line lower in capacitance leading to a faster access time. The SRAM block may be multi-port. Some multi-port access transistors may also comprise thin-film transistors. Thin film inverters may be hard-wired to a mask ROM, wherein the SRAM may be mask converted to a ROM. A ROM device may boot-up upon power up without having the need to load data from a non-volatile source.

In a second aspect, a 3D-FPGA comprises a programmable multi-port user memory block and a programmable logic block constructed on a substrate layer, and a configuration memory block to program either the memory block or the logic block constructed on a thin-film layer positioned above said substrate layer.

Implementations of the above aspect may include one or more of the following. A semiconductor integrated circuit comprises an array of programmable logic modules, memory blocks and routing resources. Each module may use one or more LUT, MUX, Product-Term, ALU, CPU and other programmable resources. An internal configuration memory block stores programming data to configure the device. Some logic and memory transistors may be fabricated on a semiconductor substrate layer. Some memory transistors may be constructed in a layer positioned above said substrate layer. Such an FPGA may comprise a very small Si foot-print, and thus offer cost and performance advantages. In one embodiment configuration memory is constructed in 3D-memory circuits. As the configuration is only useful during design de-bug phase, the 3D memory circuits may be converted to a timing-exact hard-wire circuits that allow an easy cost reduction. These products may further offer multi-port memory, wherein one set of ports may be constructed in a thin-film layer positioned above the substrate layer. Such circuits may be hard-wired to provide an instant initialization. Such advantages include cost savings from eliminating an external boot ROM, boot-up time reduction, saving valuable device pins that hook-up to the boot-ROM and saving PC-board space by eliminating the boot-ROM.

In third aspect, a plurality of physical domain nodes couples a plurality of variable node sets in a logical read domain, wherein a configuration element activates one of the sets and selects a fixed input or an address signal to decode the data read. More specifically, a programmable routing structure to couple nodes between physical and logical domains, comprising: N nodes in a physical domain, where N is an integer greater than one; and N nodes in a logical domain, said nodes arranged in a plurality of sets, each said set comprising a different number of nodes between one and N; and a plurality of routing devices, each device comprising a unique coupling scheme between the N nodes in said physical domain and the nodes of a said logical domain set, each said routing device further comprising: a configuration element to activate or deactivate the routing device; and a fixed input or an address signal to selectively couple the physical domain set nodes to logical domain N nodes is disclosed.

In a fourth aspect, a plurality of physical domain nodes couples a plurality of variable node sets in a logical write domain, wherein a configuration element activates one of the sets and couples a fixed input or an address signal to an enable signal of a driver device to decode the data written. More specifically, a programmable routing structure to couple nodes between logical and physical domains, comprises: N nodes in a logical domain, said nodes arranged in M sets, where N and M are integers greater than one, each said set comprising a different number of nodes between one and N; and N nodes in a physical domain, each node coupled to an output of a driver, each said driver further comprising: an input, and an enable signal comprising two signal levels, wherein a first level tri-states said output and a second level generates an output from said input; and M routing devices, each routing device comprising: a plurality of coupling devices to uniquely couple the nodes of a said logical domain set to the N inputs of said drivers; and a configuration bit to activate or deactivate the plurality of coupling devices; wherein, said configuration bits further couple a fixed input or an address signal to each of said enable signals to selectively couple logical domain nodes to physical domain nodes.

In a fifth aspect, logical read and logical write structures within a common port of a multi-port embedded memory array in an FPGA share one or more common decode address lines and can be configured to have different read and write data widths.

Implementations of the above aspects may include one or more of the following. One or more physical multi-port memory structures may be provided in the FPGA structure as a resource to the user. Each physical domain memory structure may comprise M×N bits arranged in M-rows (depth) and N-columns (width). A plurality of rows and a plurality of columns may be counted as one row and one column for the convenience of picking an individual cell location in a multi-port memory array. Multiple memory blocks may be concatenated to build deeper (2M, 3M, etc.) or wider (2N, 3N, etc) memory blocks. Each memory block may be further subdivided to provide smaller data width (×1, ×2, ×4, etc). Such options are configurable by the user. Logical memory may comprise a user preferred width and depth, very different from the physical structure provided in the hard-ware fabric. Typically, the user memory in the logical domain is ported to the hard-ware platform by a software tool. The logical domain may comprise a read function or a write function or both into a single port in the physical memory block. Programmable routing structures are needed to convert physical memory block(s) to the logical memory block(s) implemented by the software mapping tool. Such programmable routing structures may comprise a simple select/deselect configuration capability to identify a preferred conversion scheme amongst a plurality of conversion schemes, and an easy implementation. Such routing structures may further comprise easy to use and inexpensive to build address signals and decoders that are unique or shared by read and write functions. Such structures may comprise more efficient circuit implementations that require fewer transistors compared to prior-art techniques. Such routing structures may further comprise configuration memory elements located above a Si substrate layer used to construct logic transistors. Such routing structures may comprise pass-gate logic elements, the pass-gate controlled by a configuration memory element. Such routing structures may comprise a resistance modulating element, said element programmed between a substantially open and substantially conducting resistance levels. Such routing structures may comprise 3D memory or configurable elements. Such 3D configuration provides smaller area thus reduce cost and improve performance.

Implementations of the above aspects may also include one or more of the following. A routing structure couples physical memory to a logical read domain. A routing structure couples physical memory to a logical write domain. While the read domain and write domain provide user interface to stored memory, the memory values are stored in a common location. Thus an individual memory bit in a physical location has to be coupled to a read domain node, and a write domain node, and still maintain valid data states. Sense devices may be utilized to read data from a physical location. Registers may be used to store a read data value to support synchronous applications. Register by-pass circuitry may be employed to support asynchronous applications, and configuration elements may facilitate the user options. The data read from physical memory array may be coupled to logical read domain nodes via a plurality of routing devices. Each device may couple a fixed physical data width to a pre-selected different logical data width. The nodes in the logical read domain may comprise a plurality of sets of nodes, each set comprising a different number of nodes, to offer the user different data width option in the logical read domain. The required data-width may be selected by the user by simply configuring one or more configuration bits. A routing device may further comprise a fixed input signal comprising logic zero voltage level or logic one voltage level. That may provide an option of selecting all coupling devices within a routing device to be on or off. A routing device may further comprise a fixed input signal comprising a logic zero voltage level or an address signal. That may provide an option of selecting all coupling devices within a routing device to be off or controlled by an address value. A single address signal provides two address values, and N-address signals provide up to 2^{N} address values. The user may decode the coupling devices within a routing device using these address values. One routing device may comprise a single address signal, another routing device may comprise N-address signals. Each routing device may comprise a unique coupling scheme that allows a different number of address signals to decode the coupling scheme. Driver circuits (also called driver device in this disclosure) may be deployed to write data into the physical memory array from nodes within a logical write domain. The drivers may be tri-stated; tri-stated is defined as the condition when the outputs of said driver are cut-off from input signals to the driver circuit. When the driver is tri-stated, or equivalently when the driver outputs are tri-stated, each output is free to reach voltage driven by some other active circuit coupled to the output. The driver may comprise a single output, or a plurality of outputs. The driver may comprise two outputs comprising true and compliment polarity. The outputs may be controlled by an enable signal. The enable signal may be further addressed by a logic signal, said logic signal tri-stating a plurality of drivers. Such a signal may be used to separate write functions and read functions to prevent data corruption. The enable signal may be further generated by a decoding technique. In one instance, all enable signals may comprise a fixed input at logic zero or logic one voltage levels to activate or tri-state the driver. Then all drivers drive data into the array simultaneously. In a second instance, all drivers may receive a fixed logic zero signal or an address signal (half the drivers receiving the first address value, and the other half receiving the second address value). Then all drivers are either tri-stated, or decoded by the address value. Similarly, all drivers may receive a fixed logic zero voltage signal or one of 2^{N} address values. Such a scheme offers a decoding scheme to activate necessary drivers among a plurality of drivers to drive write data selectively into the physical memory array. Thus only selected data values within a single row of data in the physical array may be changed. The inputs of the drivers to physical memory array may be coupled to logical write domain nodes via a plurality of routing devices. Each device may couple a fixed physical data width to a pre-selected different data width. The nodes in the logical write domain may comprise a plurality of sets of nodes, each set comprising a different number of nodes, to offer the user different data width option in the logical write domain. The required data-width may be selected by the user by simply configuring one or more configuration bits. Each routing device may comprise a plurality of coupling devices to provide a unique coupling scheme between all the driver inputs and the varying number of nodes in the set. A configuration bit may activate all the coupling devices, thus selecting a specific write width in the logical domain. A configuration bit may decouple all the coupling devices, thus deselecting a data width from the logical write domain. This simple select/deselect scheme may offer a simple circuit construction and efficient routing device construction.

When a fixed 36-bit data width in the physical memory is coupled to a smaller data width in the logical read or write domains, it may be desirable to have variable data width within the same port for read and write functions. The user may desire to read data in ×1 or ×2 mode, but elect to write data in ×8 or ×36 mode, or visa-versa. The required mode is selected by activating the appropriate routing device in the read domain and the write domain. This offers use of multiple clocks to optimally manage memory applications within the design. The conversion of logical memory to physical memory requires address signals, and common address signals between read and write functions reduce the programming overhead and the number of wires needed to support embedded memory. The number of 2-input gates (=Gates) to construct a decoder circuit grows with the total number of address signals required. Assuming true and complement address signals are available; to generate four AiBi address values 4 Gates are needed. To generate 32 AiBiCiDiEi address values 56 Gates are needed, each address value incurring 3 gate delays. Thus it is very desirable to keep common address circuits for read and write domains, and keep the number of address signals required to a minimum. Depending on the data-width requirement for the read and write functions, not all address signals are needed, and it is desirable not to provide logical connections to unused address signals. Decoding circuits based on combines address and configurable signals are undesirable due to the higher gate counts encountered and the longer ensuing decoding delays. In U.S. Pat. No. 5,715,197 to generate 4 address values S0-S3 (FIG. 4) 12 Gates are used—compared to four as presented earlier. Thus a significant advantage with the current disclosure is in the reduction of decoding logic area and improvement in performance for these routing structures.

The programmable logic & memory circuits may include digital circuits consisting of CMOS transistors forming AND, NAND, INVERT, OR, NOR and pass-gate type logic circuits. Configuration circuits are used to change user choices including functionality and connectivity. Configuration circuits have memory elements and access circuitry to change stored memory data. Memory elements can be RAM or ROM. Each memory element can be a transistor or a diode or a group of electronic devices. The memory elements can be made of CMOS devices, capacitors, diodes, resistors, wires and other electronic components. The memory elements can be made of thin film devices such as thin film transistors (TFT), thin-film capacitors and thin-film diodes. The memory element can be selected from the group consisting of volatile and non volatile memory elements. The memory element can also be selected from the group comprising fuses, antifuses, SRAM cells, DRAM cells, optical cells, metal optional links, EPROMs, EEPROMs, flash, magnetic, Carbon nano-tube, resistance-modulating, electrochemical and ferro-electric elements. One or more redundant memory elements can be provided for controlling the same circuit block. The memory element can generate an output signal to control pass-gate logic. Memory element may generate a signal that is used to derive a control signal to control pass-gate logic. The control signal is coupled to MUX or Look-Up-Table (LUT) or other types of logic elements.

Logic & memory circuits are fabricated using a basic logic process used to build CMOS transistors. These transistors are formed on a P-type, N-type, epi or SOI substrate wafer. Configuration circuits, including configuration memory, constructed on same Silicon substrate take up a large Silicon foot print. That adds to the cost of programmable circuits compared to similar functionality custom wire circuits. A 3-dimensional integration of configuration circuits described in incorporated references provides a significant cost reduction in programmability. The configuration circuits may be constructed after a first contact layer is formed or above one or more metal layers. The programmable feature may be constructed as logic circuits and configuration circuits. The configuration circuits may be formed vertically above the logic circuits by inserting a thin-film transistor (TFT) module. The TFT module may include one or more metal layers for local interconnect between TFT transistors. The TFT module may include silicided poly-Silicon local interconnect lines and thin film memory elements. The thin-film module may comprise thin-film RAM elements. The thin-film memory outputs may be directly coupled to gate electrodes of pass-gates to provide programmability. Contact or via thru-holes may be used to connect TFT module to underneath layers. The thru-holes may be filled with Titanium-Tungsten, Tungsten, Tungsten Silicide, or some other refractory metal. The thru-holes may contain Nickel or other metal to assist Metal Induced Laser Crystallization (MILC) in subsequent processing. Memory elements may include TFT transistors, capacitors and diodes. Metal layers above the TFT layers may be used for all other routing. This simple vertically integrated pass-gate switch and configuration circuit reduces programmable memory cost.

Implementations of the above aspects may include one or more of the following. A programmable memory block is used for a user to implement generic designs in an FPGA. This programmability is provided to the user in an off the shelf FPGA product. There is no waiting and time lost to port synthesized logic design into a FPGA device. This reduces time to solution (TTS) by 6 moths to over a year.

A TFT module may be inserted to a logic process. Manufacturing of TFT layers add extra cost to the finished product. This cost makes programmable option less attractive to a user who has completed the design verification. Once the programming is finalized by the user, the wire connections and the RAM bit pattern is fixed for most designs during product life cycle. User programmability in the wire & LUT circuit is no longer needed and no longer valuable to the user. The user may convert the design to a lower cost hard-wire ROM circuit. The programmed choices are mapped from RAM to ROM. RAM outputs at logic one are mapped to ROM wires connected to power. RAM outputs at logic zero are mapped to ROM wires connected to ground. This may be done with a single metal mask in lieu of all of the TFT layers. Such an elimination of processing layers reduces the cost of the ROM version. A first module with memory and logic transistors does not change by this conversion. A third module may exist above the second module to complete interconnect for functionality of the end device. The third module also does not change with the second module option. A timing characteristic comprising signal delay from inputs to outputs is not changed by the memory option. The propagation delays and critical path timing in the FPGA may be substantially identical between the two second module options. The TFT layers may allow a higher power supply voltage for the user to emulate performance at reduced pass-gate resistances. Such emulations may predict potential performance improvements for TFT pass-gates and hard-wired connected options. ROM customization may be done with a thru-hole, a metal mask, or a plurality of thru-hole and metal masks. Hard wire pattern may also improve reliability and reduce defect density of the final product. The ROM pattern provides a cost economical final custom circuit (ASIC) to the user at a very low NRE cost. The total solution provides a programmable and customized solution to the user.

Implementations of the above aspect may further include one or more of the following. The programmable circuit comprises a RAM element that can be selected from the group consisting of volatile or non volatile memory elements. The memory can be implemented using a TFT process technology that contains one or more of Fuses, Anti-fuses, DRAM, EPROM, EEPROM, Flash, resistance-modulating, Carbon nano-tube, Ferro-Electric, optical, magnetic, electro-chemical and SRAM elements. Configuration circuits may include thin film elements such as diodes, transistors, resistors and capacitors. The process implementation is possible with any memory technology where the programmable element is vertically integrated in a removable module. The manufacturing options include a conductive ROM pattern in lieu of memory circuits to control the logic circuits. Multiple memory bits exist to customize wire connections inside memory blocks, inside a logic block and between logic and memory blocks. Each RAM bit pattern has a corresponding unique ROM pattern to duplicate the same functionality.

The programmable memory structures described constitutes fabricating a VLSI IC product. The IC product is re-programmable in its initial stage with turnkey conversion to a one mask customized ASIC. The IC has the end ASIC cost structure and initial FPGA re-programmability. The IC product offering occurs in two phases: the first phase is a generic FPGA that has re-programmability contained in a programmable circuit, and a second phase is an ASIC that has the entire programmable module replaced by one or more customized hard-wire masks. Both FPGA version and turnkey custom ASIC has the same base die. No re-qualification is required by the conversion. The vertically integrated programmable module does not consume valuable Silicon real estate of a base die. Furthermore, the design and layout of these product families adhere to removable module concept: ensuring the functionality and timing of the product in its FPGA and ASIC canonicals. These IC products can replace existing PLD's, CPLD's, FPGA's, Gate Arrays, Structured ASIC's and Standard Cell ASIC's. An easy turnkey customization of an end ASIC from an original smaller cheaper and faster programmable structured array device would greatly enhance time to market, performance, product reliability and solution cost.

### BRIEF DESCRIPTION OF THE DRAWINGS

FIG. 1A shows an exemplary MUX or LUT based logic element.

FIG. 1B shows an exemplary programmable wire structure utilizing a logic element.

FIG. 2A shows an exemplary FPGA comprising multiple embedded memory blocks.

FIG. 2B shows an exemplary routing block for the embedded memory block in FIG. 2A.

FIG. 3A-3D shows various examples of point to point connections (i.e. switches).

FIG. 3E shows an exemplary configuration circuit comprising a 6T SRAM element.

FIG. 3F shows an exemplary programmable pass-gate (switch) with SRAM memory.

FIG. 3G shows a modular construction of 3D Memory/Logic circuits.

FIG. 4A shows a dual-port RAM array to be used with the present invention.

FIG. 4B shows a single dual-port SRAM cell in FIG. 3A array.

FIG. 5.1-5.7 shows process cross-sections for 3D thin-film transistors integration.

FIG. 6A-6B shows a 2-node novel routing structure between physical & logical memory.

FIG. 7A shows a first embodiment of a four node routing structure for READ function.

FIG. 7B shows a second embodiment of a four node routing structure for READ function.

FIG. 7C shows a block diagram of the routing structure in FIG. 7A or 7B.

FIG. 8A shows a first embodiment of a four node routing structure for WRITE function.

FIG. 8B shows a programmable driver circuit to be used in FIG. 8A.

FIG. 8C shows a block diagram of the routing structure in FIG. 8A.

FIG. 9 shows a routing structure for READ and WRITE functions within the same port.

FIG. 10 shows unique routing devices deployed in FIG. 9 for READ and WRITE functions.

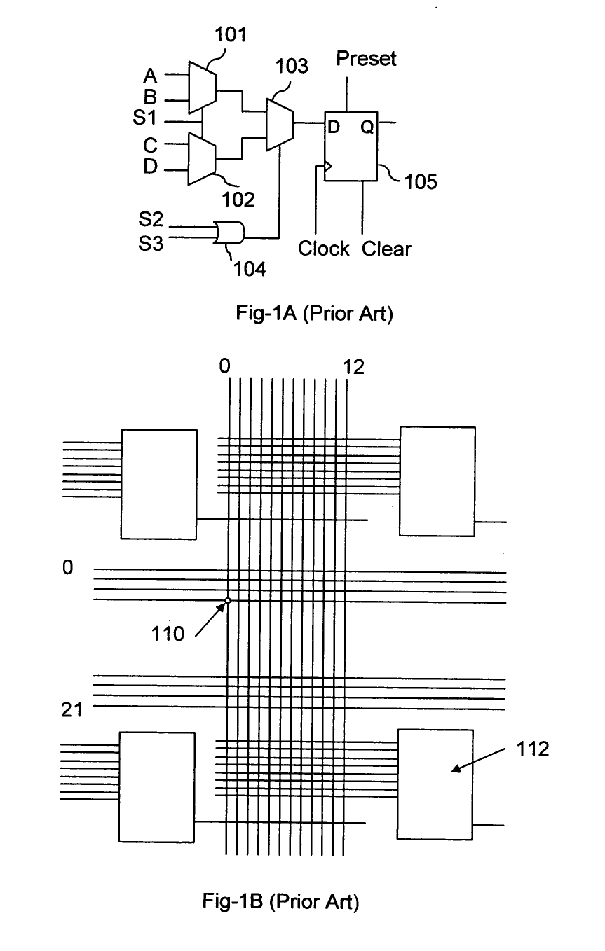

### DESCRIPTION

In the following detailed description of the invention, reference is made to the accompanying drawings which form a part hereof, and in which is shown, by way of illustration, specific embodiments in which the invention may be practiced. These embodiments are described in sufficient detail to enable those skilled in the art to practice the invention. Other embodiments may be utilized and structural, logical, and electrical changes may be made without departing from the scope of the present invention.

Definitions: The terms wafer and substrate used in the following description include any structure having an exposed surface with which to form the integrated circuit (IC) structure of the invention. The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductor layers supported by a base semiconductor or insulator, SOI material as well as other semiconductor structures well known to one skilled in the art. The term conductor is understood to include semiconductors, and the term insulator is defined to include any material that is less electrically conductive than the materials referred to as conductors.

The term module layer includes a structure that is fabricated using a series of predetermined process steps. The boundary of the structure is defined by a first step, one or more intermediate steps, and a final step in a process. The resulting structure is formed on a substrate.

The term pass-gate (also called a switch) refers to a structure that can pass a signal when on, and block a signal passage when off. A pass-gate couples two points when on, and decouples two points when off. A pass-gate can be a floating-gate transistor, an NMOS transistor, a PMOS transistor or a CMOS transistor pair. The gate electrode of pass-gate determines the state of the connection. A CMOS pass-gate requires complementary signals coupled to NMOS and PMOS gate electrodes. A control logic signal is connected to gate electrode of a pass-gate for programmable logic. A pass-gate can be a resistance modulating element (such as capacitor, resistor, etc.) that comprises substantially conductive and substantially non-conductive states. A configuration circuit is coupled to a pass-gate element to alter the resistance between the conducting and non-conducting states. A pass-gate comprises a configurable element.

The term memory circuit includes one or more storage elements and access circuitry to evaluate and or alter the stored data. The term configuration circuit includes one or more configurable elements and connections that can be programmed for controlling one or more circuit blocks in accordance with a predetermined user-desired functionality. The configuration circuit includes the memory element and the access circuitry to modify said memory element. It is understood that configuration circuits are a subset of memory circuits. For transistor pass-gates, configuration circuit does not include the logic pass-gate transistor controlled by the memory element. For resistance pass-gates, the configuration circuit includes the configurable conducting element that governs the resistance. For capacitive pass-gates, the configuration circuit includes the configurable capacitive element that governs ON/OFF states. In one embodiment, the configuration circuit includes a plurality of RAM circuits to store instructions to configure an FPGA. In another embodiment, the configuration circuit includes a first selectable configuration where a plurality of RAM circuits is formed to store instructions to control one or more circuit blocks, and a second selectable configuration with a predetermined ROM conductive pattern formed in lieu of the RAM circuit to control substantially the same circuit blocks. In yet another embodiment, the configuration circuit includes a plurality of monolithic ROM circuits to store instructions to configure an FPGA. The memory circuit includes elements such as diode, transistor, resistor, capacitor, metal link, wires, among others. The memory circuit also includes thin film elements. In yet another embodiment, the configuration circuits include a predetermined conductive pattern, contact, via, resistor, capacitor or other suitable circuits formed in lieu of the memory circuit to control substantially the same circuit blocks.

The term “horizontal” as used in this application is defined as a plane parallel to the conventional plane or surface of a wafer or substrate, regardless of the orientation of the wafer or substrate. The term “vertical” refers to a direction perpendicular to the horizontal direction as defined above. Prepositions, such as “on”, “side”, “higher”, “lower”, “over” and “under” are defined with respect to the conventional plane or surface being on the top surface of the wafer or substrate, regardless of the orientation of the wafer or substrate.

The term fixed input is defined to be a logic zero or a logic one input. The terms address signal and address line are defined to be a signal that allows addressing a subset of values within a set. An individual value in a set of 2^{N} values can be addressed by N address signals. Conversely, N address signals comprise 2^{N} address values. Similarly, to address an individual value in a set of (2^{N}+1) values, (N+1) address lines are needed wherein some address values are undefined. Address signals are also used to address a plurality of values within the set. For example, one address line is used to extract a first 2^{(N-1)} values and a second 2^{(N-1)} values in a set of 2^{N} values. Address signals are coupled to a structure to facilitate the selection.

The term physical memory domain refers to a memory block comprising a fixed depth M and a fixed width N (M and N are integers) within the hard-ware. The depth is measured in rows, and comprises M rows. Each row may further comprise a pair of rows in a dual-port memory structure. The width is measured in columns, and comprises N columns. Each column may further comprise two pairs of columns in a dual-port memory structure. A plurality of physical memory blocks is provided in a pre-fabricated FPGA, each comprising a fixed depth and width. The term logical memory domain refers to a user implemented logic block in the FPGA. Typically a software tool implements the user read or write function. When a read function is implemented, the term logical read domain is used, and when a write function is implemented the term logical write domain is used. A logical memory block may be smaller than, or equal to, or larger than the physical memory block. In one embodiment, the logical memory comprises a variable depth, said depth constructed by a partial, a complete, or a plurality of physical memory blocks. In another embodiment, the logical memory comprises a variable width, said width constructed by a partial, a complete, or a plurality of physical memory blocks. Concatenating such memory blocks is accomplished by configuration circuits. The following detailed description is, therefore, not to be taken in a limiting sense.

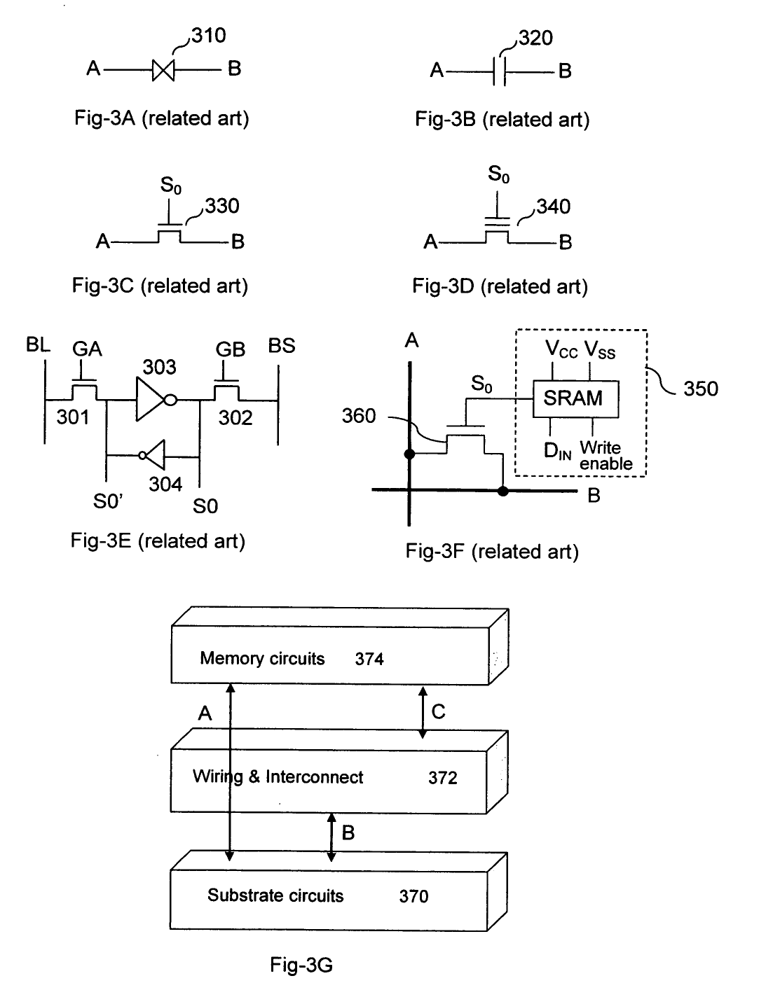

Programmable structures use point to point connections that utilize programmable pass-gate logic as shown in FIG. 3A-FIG. 3D. In FIG. 3A, a fuse or a resistance modulating element 310 provides the coupling means. In FIG. 3B, a capacitor or a resistance modulating element 320 provides the coupling means. In FIG. 3C, a pass-gate transistor comprising a gate control signal 330 provides the coupling means. In FIG. 3D, a floating pass-gate element 340 comprising the means to store injected charge provides the coupling means. Multiple inputs (node A) can be connected to multiple outputs (node B) with a plurality of pass-gate logic elements. All of the programmable elements are configured by configuration circuits. An SRAM 350 configured pass-gate 360 connection shown in FIG. 3F. The pass-gate 360 could be constructed as PMOS, NMOS or CMOS transistor pair controlled by the output of SRAM 350. The voltage S₀ on NMOS 360 gate electrode determines an ON or OFF connection. In FIG. 3E, the SRAM is shown to have back-to-back inverters 303, 304 forming a storage latch, and access devices 301, 302 to configure the latch. In FIG. 3F, the SRAM cell 350 is in the configuration circuit. In a first embodiment pass-gate 360 is in the logic circuit, and in a second embodiment pass-gate 360 is in the configuration circuit. This memory element can be configured by the user to select the polarity of S₀, thereby selecting the status of the connection. The memory element can be volatile or non-volatile. In volatile memory, it could be DRAM, SRAM, Optical or any other type of a memory device that can output a valid signal S₀. In non-volatile memory it could be fuse, anti-fuse, Metal-ROM, EPROM, EEPROM, Flash, Ferro-Electric, Magnetic, Electro-chemical, Optical, Neuron, Fiber or any other kind of memory device that can either output a valid signal S₀, or achieve a state-change. The output S₀ can be a direct output coupled to the memory element, or a derived output from the configuration circuitry. A restoring device such as an inverter can be used to restore S₀ signal level to full rail voltage levels. The SRAM in configuration circuit 350 can be operated at an elevated Vcc level to output an elevated S₀ voltage level. This is especially feasible when the SRAM is built in a separate TFT module. These configuration circuits, and similarly constructed other configuration circuits, can be used in programmable logic devices. Those with ordinary skill in the art may recognize other methods for constructing configuration circuits to generate a valid S₀ output. In a 3D construction, the pass-gate logic element is not affected by the choice of the configuration circuit.

A cheaper method of constructing a vertically integrated SRAM cell is described in incorporated-by-reference application Ser. No. 10/413,810. In a preferred embodiment, the memory circuit is built on thin-film semiconductor layers located vertically above the logic circuits. The SRAM memory element comprising a thin-film transistor (TFT) CMOS latch as shown in FIG. 3E comprises: two lower performance back to back inverters 303, 304 formed on a semiconductor thin film module layer, substantially different from a semiconductor substrate module layer comprising a logic transistor with poly-silicon gate electrode. This TFT latch is stacked above the logic circuits for slow memory applications with no penalty on Silicon area and cost. This latch is adapted to receive power and ground voltages in addition to configuration signals. The two programming access transistors for the TFT latch 301, 302 are also formed on thin-film layers. Thus all six configuration transistors in 350 are constructed in TFT layers. In a first embodiment, transistor 360 is in the conducting path of the connection and needs to be a high performance single crystal Silicon transistor in the substrate module. In a second embodiment the pass-gate 360 comprises a state-change material, and is incorporated within the thin-film module. These vertical integrations make it economically feasible to add an memory based configuration circuit at a very small cost overhead to create a programmable solution. Such vertical integration can be extended to all other memory elements that can be vertically integrated above logic circuits.

A new kind of a programmable logic device utilizing 3D configuration circuits is disclosed in incorporated-by-reference application Ser. No. 10/267,483, application Ser. No. 10/267,484 and application Ser. No. 10/267,511. The disclosures describe a programmable logic device and an application specific device fabrication from the same base Silicon die. The PLD is fabricated with a programmable RAM module, while the ASIC is fabricated with a conductive ROM pattern in lieu of the RAM. Both RAM module and ROM module provide identical control of logic circuits. For each set of RAM bit patterns, there is a unique ROM pattern to achieve the same logic functionality. The vertical integration of the configuration circuit leads to a significant cost reduction for the PLD, and the elimination of TFT memory for the ASIC allows an additional cost reduction for the user. The TFT vertical memory integration scheme is briefly described next.

FIG. 3G shows a 3D-FPGA construction. The memory circuits 374 are located above substrate logic circuits 370. The memory element can be any one of fuse links, anti-fuse capacitors, SRAM cells, DRAM cells, metal optional links, EPROM cells, EEPROM cells, flash cells, ferro-electric elements, electro-chemical elements, optical elements, Carbon nano-tubes, state-change materials and magnetic elements that lend to this implementation. SRAM memory is used herein to illustrate the scheme and is not to be taken in a limiting sense. First, Silicon transistors 370 are deposited on a substrate. A module layer of removable memory cells 374 are positioned above the Silicon transistors 370, and a module layer of interconnect wiring or routing circuit 372 is formed either above (not shown) or below (as shown) the removable memory circuits 374. To allow this replacement, the design adheres to a hierarchical layout structure. As shown in FIG. 3G, the interconnect module is sandwiched between the single crystal device layers below and the configuration circuit layers above electrically connecting to both. It also provides through connections “A” for the lower device layers to couple to upper device layers, and connections A, C for device layers to couple interconnect layers. The SRAM module contains no switching electrical signal routing inside the module. All such routing is in the layers below. Most of the programmable element configuration signals run inside the module. Upper layer connections to interconnect module “C” are minimized to Power, Ground and high drive data wires. Connections “A” between SRAM module and single crystal module only contain logic level signals and replaced later by Vcc and Vss wires. Most of the replaceable programmable elements and its configuration wiring is in the “replaceable module” while all the devices and wiring for the end ASIC is outside the “replaceable module”. In other embodiments, the replaceable module could exist between two metal layers or any other location satisfying the same device and routing constraints. This description is equally applicable to any other configuration memory element, and not limited to SRAM cells.

Fabrication of the IC also follows a modularized device formation. Formation of transistors 370 and routing 372 is by utilizing a standard logic process flow used in the ASIC fabrication. Extra processing steps used for memory element 374 formation are added onto the logic flow after interconnect layer 372 is constructed. A full disclosure of the vertical integration of the TFT module using extra masks and extra processing is in the incorporated by reference applications listed above. During the ROM customization, the base die and the data in those remaining mask layers do not change making the logistics associated with chip manufacture simple. Removal of the SRAM module provides a low cost standard logic process for the final ASIC construction with the added benefit of a smaller die size. The design timing is unaffected by this migration as lateral metal routing and Silicon transistors are untouched. Software verification and the original FPGA design methodology provide a guaranteed final ASIC solution to the user. A full disclosure of the ASIC migration from the original FPGA is in the incorporated by reference applications discussed above.

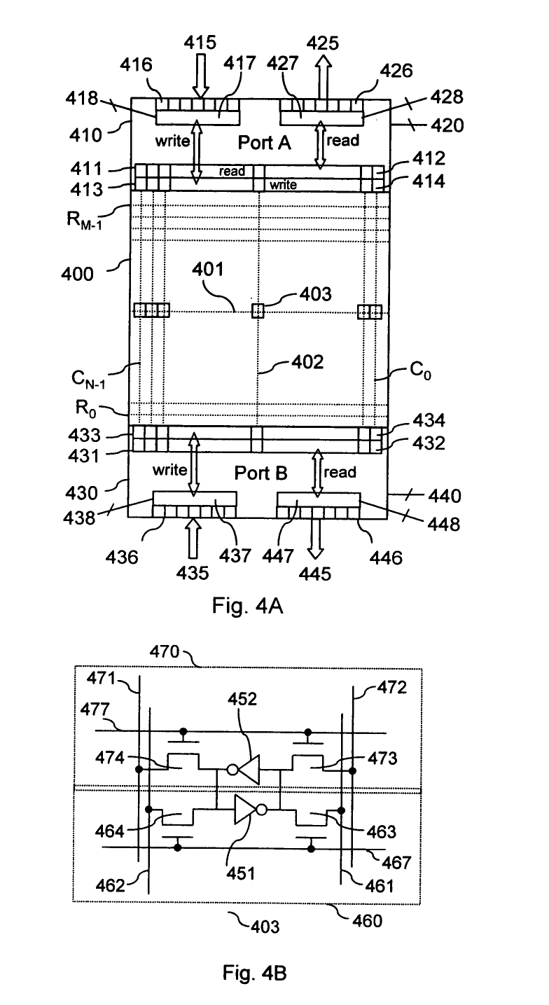

In a first embodiment, a 3D FPGA comprises a first module layer having a plurality of circuit blocks including a memory block, and a second module layer positioned above the first module layer having a configuration circuit to program a circuit block. In a second embodiment, a 3D FPGA comprises a first module layer having a plurality of circuit blocks and a memory block, and a second module layer positioned above the first module layer having a configuration circuit to program a circuit block and the memory block. In a third embodiment, a 3D FPGA comprising an embedded user memory block comprises a semiconductor thin-film transistor positioned above a semiconductor substrate comprising a logic transistor. The user memory in the 3D FPGA includes single-port or multi-port SRAM, DRAM, Flash, or any other type of memory. A dual-port physical memory block used in the current invention is described next, and shown in FIG. 4A. A dual-port memory construction is discussed for illustrative purposes and should not be taken in a limiting sense. The dual-port memory array 400 is arranged in M-deep×N-wide array of dual-port memory cells 403. M and N are integer values, and in a preferred embodiment, M=256, and N=36. A detailed view of an individual cell 403 is provided in FIG. 4B, and is discussed later. The array 400 comprises R₀-R_{M-1} pairs of M row-lines such as 401, and C₀-C_{N-1} dual-pairs of N column-lines such as 402. The memory block has a Port-A 410 and a Port-B 430, each capable of providing READ and WRITE functions independently. One row line and one pair of column lines are dedicated to each port. Within port-A 410, a plurality of address lines 420 provides the row-line decoding. For M rows, (Log₁₀M/Log₁₀2, rounded-up) address lines are needed for decoding. These address lines 420 are shared by the WRITE and READ functions at that port. For the WRITE function at port 410, there is a logical write bus 415 and a physical write bus 413. The two buses 415 and 413 are coupled to each other by a programmable routing device 417. The logical bus 415 comprises up-to N nodes such as 416. The user selects a subset of N-nodes (such as 1, 2, 4, 8, 9, 16, 18, 32, 36 for the N=36 example) based on the user need in the logical memory to interface with the physical memory block. Each subset comprises an integer number of nodes between one and N, the full physical width of the memory block. These subsets are pre-defined to the user. In a preferred embodiment, these are programmable. To allow this choice, address lines 418, specialized circuits and configurability as disclosed later are used in circuit block 417. The physical bus 413 comprises a fixed number of N driver circuits such as 414, each driver circuit comprising a storage unit and write circuitry, and each driver circuit coupled to a column line pair such as 402 to write data into a physical memory location such as 403. For the READ function at port 410, there is a logical read bus 425 and a physical read bus 411. The two buses 425 and 411 are coupled to each other by a programmable routing device 427. The logical bus 425 comprises up-to N nodes such as 426. The user selects a subset of N-nodes (such as 1, 2, 4, 8, 9, 16, 18, 32, 36 for the N=36 example) based on the user need to interface logical memory with the physical memory block. These subsets are also pre-defined to the user, and may or may not match with the write function. In a preferred embodiment the choices offered for READ and WRITE logical data widths are the same, but the user may elect to use different READ and WRITE data widths at the same port 410. To allow the variable data width choice, address lines 428, specialized circuits and configurability as disclosed later is used in circuit block 427. The address lines 418 and 428 may be common, or may differ. In a preferred embodiment, address lines 418 and 428 are common, but READ and WRITE widths are still independently configured. The physical bus 411 comprises a fixed number of N sense circuits such as 412, each sense circuit comprising a storage unit and read circuitry, and each sense circuit coupled to a column line pair such as 402 to read data from a physical memory location such as 403. The column line pair and the word line are shared by the READ and the WRITE functions within one port. Both read and write circuitry offer a plurality of programmable control signals such as clock signals, clock inverts, latch by-pass, clock-enable, set and reset among others. These control logic also offer programmable choices, such as clock-invert, clock delays, multiple clocks, etc. The programmable elements are configured by the configuration circuits.

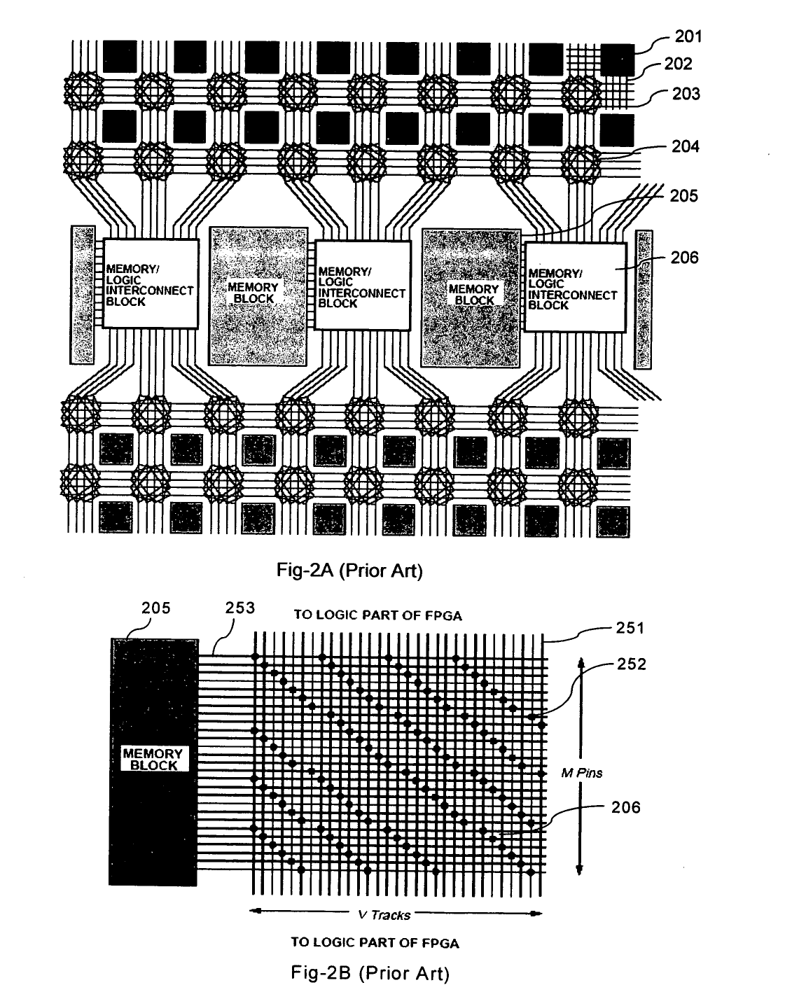

The Port-A 410 for memory block 400 is coupled to FPGA routing resources (see wires 253 in FIG. 2B) via data wires 415, 425, address wires 418, 428, 420 and control logic signals (not shown) for the supporting circuitry. These routing choices are programmable. In port 410, at any given time, either a READ, or a WRITE, or both READ & WRITE instructions may be executed; however, such instructions are confined to the N-bit wide data located in a single row-line location selected by the address-lines 420. Simultaneous logical READ and logical WRITE features are easily arranged from different physical-bit locations within the same row-line. Simultaneous logical READ and logical WRITE to “identical” physical-bit locations is managed by additional “conflict-avoidance” logic circuitry. Port-B 430 is similar to Port-A 410, and the above description for Port-A can be used by the reader to extract its functionality. In some constructions, Port-B may have lesser or greater functionality compared to Port-A.

An individual dual-port SRAM cell at location 403 is shown in detail in FIG. 4B. The cell 403 comprises a set of Port-A connections inside 470, and a set of Port-B connections inside 460. The back-to-back inverter pair 451, 452 provides a latch to store data. Any other storage element may be used. In Port-A 470, row line 477 and column lines pair 471, 472 provide the decoded means of accessing the latch via transistors 473 and 474. Both column lines 471, 472 are asserted during dual-ended read and dual-ended write design techniques. In some applications, single ended read and write techniques are preferred. In Port-B 460, row line 467 and column lines pair 461, 462 provide the decoded means of accessing the same latch via transistors 463 and 464. Both column lines 461, 462 are asserted during a dual-ended read and write operation. Row line 477 for Port-A 470 in FIG. 4B is decoded via the address lines 420 in Port-A 410 in FIG. 4A, while row line 467 for Port-B 460 in FIG. 4B is decoded via the address lines 440 in Port-B 430 in FIG. 4A. The address lines 420 and 440 are separate sets. The column address for Port-A is via address lines 428 (and/or 418) and for Port-B is via address lines 448 (and/or 438).

As there are two sets of row address-lines in memory 400, Port-A and Port-B can access data stored at two different row line locations simultaneously. The two ports can READ data either at two row address locations, or the same row address location simultaneously. The two ports can WRITE data to two row address locations, but cannot WRITE data to same row address location simultaneously. READ and WRITE functions can also occur simultaneously, and “conflict-avoidance” circuits are used to manage READ/WRITE and WRITE/WRITE conflicts at the same physical bit location.

Dual-port memory and configuration memory using SRAM process technology benefit from 3D circuit integration. Portions of these circuits can be constructed in thin-film-transistors (TFT) located above Silicon transistors to reduce construction area. Specifically static circuits such as feed-back inverters offer an excellent opportunity for vertical TFT constructions, as those circuits need not be high performance. Furthermore, they do not consume static power as very little to no switching is encountered, and these circuits generally maintain static voltage levels. The fabrication of thin-film transistors to construct these circuits is discussed next. A full disclosure is provided in incorporated by reference application Ser. No. 10/413,809. The following terms used herein are acronyms associated with certain manufacturing processes. The acronyms and their abbreviations are as follows:

V_{T} Threshold voltage

LDN Lightly doped NMOS drain

LDP Lightly doped PMOS drain

LDD Lightly doped drain

RTA Rapid thermal annealing

Ni Nickel

Co Cobalt

Ti Titanium

TiN Titanium-Nitride

W Tungsten

S Source

D Drain

G Gate

ILD Inter layer dielectric

C1-Contact-1

M1 Metal-1

P1 Poly-1

P− Positive light dopant (Boron species, BF₂)

N− Negative light dopant (Phosphorous, Arsenic)

P+ Positive high dopant (Boron species, BF₂)

N+ Negative high dopant (Phosphorous, Arsenic)

Gox Gate oxide

C2 Contact-2

LPCVD Low pressure chemical vapor deposition

CVD Chemical vapor deposition

ONO Oxide-nitride-oxide

LTO Low temperature oxide

A logic process is used to fabricate CMOS devices on a substrate layer for the fabrication of logic circuits. These CMOS devices may be used to build AND gates, OR gates, inverters, adders, multipliers, memory and pass-gate based logic functions in an integrated circuit. A CMOSFET TFT module layer or a Complementary gated FET (CGated-FET) TFT module layer may be inserted to a logic process at a first contact mask to build a second set of TFT MOSFET or Gated-FET devices. Configuration circuitry including RAM elements is build with these second set of transistors. An exemplary logic process may include one or more following steps:

P-type substrate starting wafer

Shallow Trench isolation: Trench Etch, Trench Fill and CMP

Sacrificial oxide deposition

PMOS V_{T} mask & implant

NMOS V_{T} mask & implant

Pwell implant mask and implant through field

Nwell implant mask and implant through field

Dopant activation and anneal

Sacrificial oxide etch

Gate oxidation/Dual gate oxide option

Gate poly (GP) deposition

GP mask & etch

LDN mask & implant

LDP mask & implant

Spacer oxide deposition & spacer etch

N+ mask and NMOS N+G, S, D implant

P+ mask and PMOS P+G, S, D implant

Co deposition

RTA anneal—Co silicidation (S/DIG regions & interconnect)

Unreacted Co etch

ILD oxide deposition & CMP

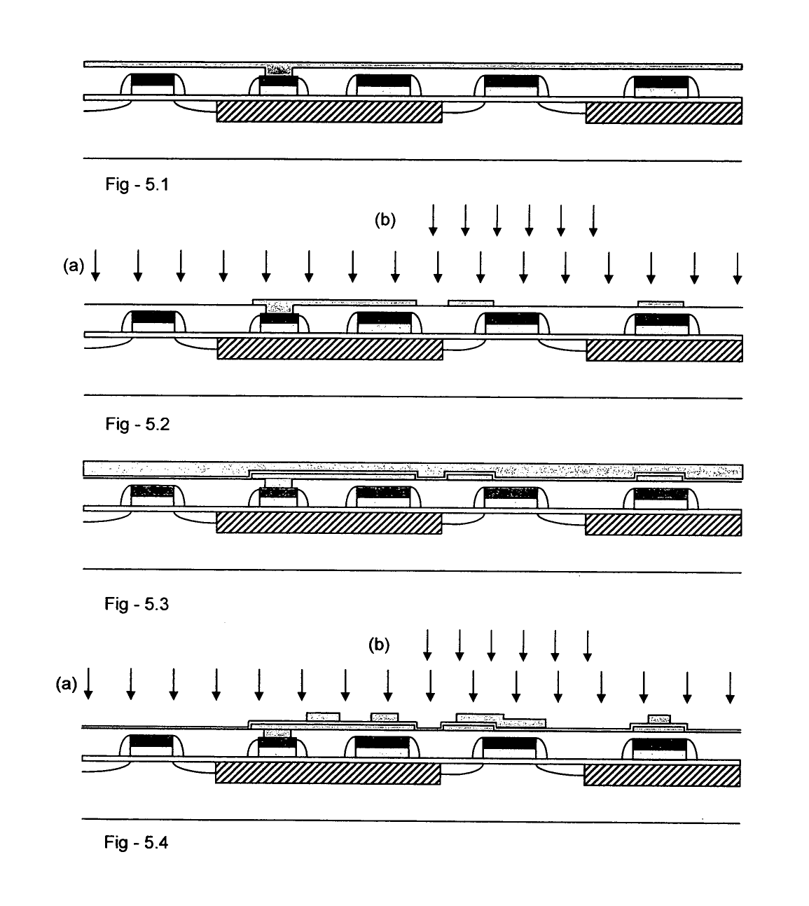

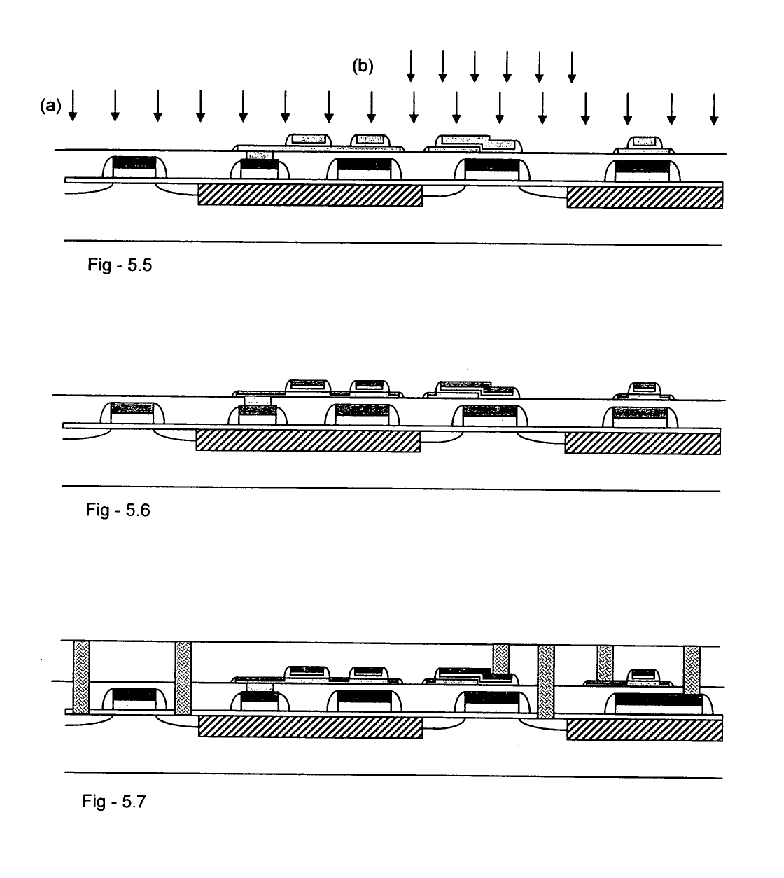

FIG. 5 shows an exemplary process for fabricating a thin film MOSFET latch in a second module layer. In one embodiment the process in FIG. 5 forms the configuration latch and/or one inverter of dual-port SRAM latch in a layer substantially above the substrate layer. The processing sequence in FIG. 5.1 through FIG. 5.7 describes the physical construction of a MOSFET device for storage circuits 350 shown in FIG. 3F or a portion of circuits 403 in FIG. 4B. The process of FIG. 5 includes adding one or more following steps to the logic process after ILD oxide deposition & CMP step in the logic process.

C1 mask & etch

W-Silicide plug fill & CMP

˜250 A poly P1 (amorphous poly-1) deposition

P1 mask & etch

Blanket Vtn P− implant (NMOS Vt)

Vtp mask & N− implant (PMOS Vt)

TFT Gox (70 A PECVD) deposition

400 A P2 (amorphous poly-2) deposition

P2 mask & etch

Blanket LDN NMOS N− tip implant

LDP mask and PMOS P− tip implant

Spacer LTO deposition

Spacer LTO etch to form spacers & expose P1

Blanket N+ implant (NMOS G/S/D & interconnect)

P+ mask & implant (PMOS G/S/D & interconnect)

Ni deposition

RTA silicidation and poly re-crystallization (G/S/D regions & interconnect)

Dopant activation anneal

Excess Ni etch

ILD oxide deposition & CMP

C2 mask & etch

W plug formation & CMP

M1 deposition and back end metallization

The TFT process technology consists of creating NMOS & PMOS poly-Silicon transistors. In the embodiment in FIG. 5, the module insertion is after the substrate device gate-poly etch and ILD film deposition. In other embodiments the insertion point may be after M1 and ILD deposition, prior to V1 mask, or between two metal definition steps, or at the top of last metal layer.

After gate poly of regular transistors are patterned and etched, the poly is silicided using Cobalt & RTA sequences. Then the ILD is deposited, and polished by CMP techniques to a desired thickness. In the shown embodiment, the contact mask is split into two levels. The first C1 mask contains all contacts that connect TFT latch outputs to substrate transistor pass-gates. This C1 mask is used to open and etch contacts in the ILD film. Ti/TiN glue layer followed by W-Six plugs, W plugs or Si plugs may be used to fill the plugs, then CMP polished to leave the fill material only in the contact holes. The choice of fill material is based on the thermal requirements of the TFT module. In another embodiment, Ni is introduced into C1 to facilitate crystallization of the poly Silicon deposited over the contacts. This Ni may be introduced as a thin layer after the Ti/TiN glue layer is deposited, or after W is deposited just to fill the center of the contact hole.

Then, a desired thickness of first P1 poly, amorphous or crystalline, is deposited by LPCVD as shown in FIG. 5.1. The P1 thickness is between 50 A and 1000 A, and preferably 250 A. This poly layer P1 is used for the channel, source, and drain regions for both NMOS and PMOS TFT's. It is patterned and etched to form the transistor body regions. In other embodiments, P1 is used for contact pedestals. NMOS transistors are blanket implanted with P− doping, while the PMOS transistor regions are mask selected and implanted with N− doping. This is shown in FIG. 5.2. The implant doses and P1 thickness are optimized to get the required threshold voltages for PMOS & NMOS devices under fully depleted transistor operation, and maximize on/off device current ratio. The pedestals implant type is irrelevant at this point. In another embodiment, the V_{T} implantation is done with a mask P− implant followed by masked N− implant. First doping can also be done in-situ during poly deposition or by blanket implant after poly is deposited.

Patterned and implanted P1 may be subjected to dopant activation and crystallization. In one embodiment, an RTA cycle with Ni as seed in C1 is used to activate & crystallize the poly before or after it is patterned to near single crystal form. In a second embodiment, the gate dielectric is deposited, and buried contact mask is used to etch areas where P1 contacts P2 layer. Then, Ni is deposited and silicided with RTA cycle. All of the P1 in contact with Ni is silicided, while the rest poly is crystallized to near single crystal form. Then the un-reacted Ni is etched away. In a third embodiment, amorphous poly is crystallized prior to P1 patterning with an oxide cap, metal seed mask, Ni deposition and MILC (Metal-Induced-Lateral-Crystallization).

Then the TFT gate dielectric layer is deposited followed by P2 layer deposition. The dielectric is deposited by PECVD techniques to a desired thickness in the 30-200 A range, desirably 70 A thick. The gate may be grown thermally by using RTA. This gate material could be an oxide, nitride, oxynitride, ONO structure, or any other dielectric material combinations used as gate dielectric. The dielectric thickness is determined by the voltage level of the process. At this point an optional buried contact mask (BC) may be used to open selected P1 contact regions, etch the dielectric and expose P1 layer. BC could be used on P1 pedestals to form P1/P2 stacks over C1. In the P1 silicided embodiment using Ni, the dielectric deposition and buried contact etch occur before the crystallization. In the preferred embodiment, no BC is used.

Then second poly P2 layer, 100 A to 2000 A thick, preferably 400 A is deposited as amorphous or crystalline poly-Silicon by LPCVD as shown in FIG. 5.3. P2 layer is defined into NMOS & PMOS gate regions intersecting the P1 layer body regions, C1 pedestals if needed, and local interconnect lines and then etched. The P2 layer etching is continued until the dielectric oxide is exposed over P1 areas uncovered by P2 (source, drain, P1 resistors). The source & drain P1 regions orthogonal to P2 gate regions are now self aligned to P2 gate edges. The S/D P2 regions may contact P1 via buried contacts. NMOS devices are blanket implanted with LDN N-dopant. Then PMOS devices are mask selected and implanted with LDP P− dopant as shown in FIG. 5.4. The implant energy ensures full dopant penetration through the residual oxide into the S/D regions adjacent to P2 layers.

A spacer oxide is deposited over the LDD implanted P2 using LTO or PECVD techniques. The oxide is etched to form spacers. The spacer etch leaves a residual oxide over P1 in a first embodiment, and completely removes oxide over exposed P1 in a second embodiment. The latter allows for P1 silicidation at a subsequent step. Then NMOS devices & N+ poly interconnects are blanket implanted with N+. The implant energy ensures full or partial dopant penetration into the 100 A residual oxide in the S/D regions adjacent to P2 layers. This doping gets to gate, drain & source of all NMOS devices and N+ interconnects. The P+ mask is used to select PMOS devices and P+ interconnect, and implanted with P+ dopant as shown in FIG. 5.5. PMOS gate, drain & source regions receive the P+ dopant. This N+/P+ implants can be done with N+ mask followed by P+ mask. The V_{T} implanted P1 regions are now completely covered by P2 layer and spacer regions, and form channel regions of NMOS & PMOS transistors.

After the P+/N+ implants, Nickel is deposited over P2 and silicided to form a low resistive refractory metal on exposed poly by RTA. Un-reacted Ni is etched as shown in FIG. 5.6. This 100 A-500 A thick Ni-Silicide connects the opposite doped poly-2 regions together providing low resistive poly wires for data. In one embodiment, the residual gate dielectric left after the spacer prevents P1 layer silicidation. In a second embodiment, as the residual oxide is removed over exposed P1 after spacer-etch, P1 is silicided. The thickness of Ni deposition may be used to control full or partial silicidation of P1 regions. Fully silicided S/D regions up to spacer edge facilitate high drive current due to lower source and drain resistances.

An LTO film is deposited over P2 layer, and polished flat with CMP. A second contact mask C2 is used to open contacts into the TFT P2 and P1 regions in addition to all other contacts to substrate transistors. In the shown embodiment, C1 contacts connecting latch outputs to substrate transistor gates require no C2 contacts. Contact plugs are filled with tungsten, CMP polished, and connected by metal as done in standard contact metallization of IC's as shown in FIG. 5.7.

A TFT process sequence similar to that shown in FIG. 5 can be used to build complementary Gated-FET thin film devices. Compared with CMOS devices, these are bulk conducting devices and work on the principles of JFETs. A full disclosure of these devices is provided in incorporated by reference application Ser. No. 10/413,808. The process steps facilitate the device doping differences between MOSFET and Gated-FET devices, and simultaneous formation of complementary Gated-FET TFT devices. A detailed description for this process was provided when describing FIG. 5 earlier and is not repeated. An exemplary CGated-FET process sequence may use one or more of the following steps:

C1 mask & etch

W-Silicide plug fill & CMP (optional Ni seed in W-plug)

˜300 A poly P1 (amorphous poly-1) deposition

Optional poly crystallization

P1 mask & etch

Blanket Vtn N− implant (Gated-NFET V_{T})

Vtp mask & P− implant (Gated-PFET V_{T})

TFT Gox (70 A PECVD) deposition

500 A P2 (amorphous poly-2) deposition

Blanket P+ implant (Gated-NFET gate & interconnect)

N+ mask & implant (Gated-PFET gate & interconnect)

P2 mask & etch

Blanket LDN Gated-NFET N tip implant

LDP mask and Gated-PFET P tip implant

Spacer LTO deposition

Spacer LTO etch to form spacers & expose P1

Ni deposition

RTA silicidation and poly re-crystallization (exposed P1 and P2)

Fully silicidation of exposed P1 S/D regions

Dopant activation anneal

Excess Ni etch

ILD oxide deposition & CMP

C2 mask & etch

W plug formation & CMP

M1 deposition and back end metallization

As the discussions demonstrate memory either as multi-port or user memory blocks or to store instructions to configure programmable logic elements provides a significant opportunity for 3D integration for FPGA devices. The typically incurred high cost of memory can be drastically reduced by the 3D integration, and the replaceable memory concept further provide timing exact conversion of FPGA to one custom mask ASIC. Specific circuits to enclose memory blocks within an FPGA fabric is disclosed next.

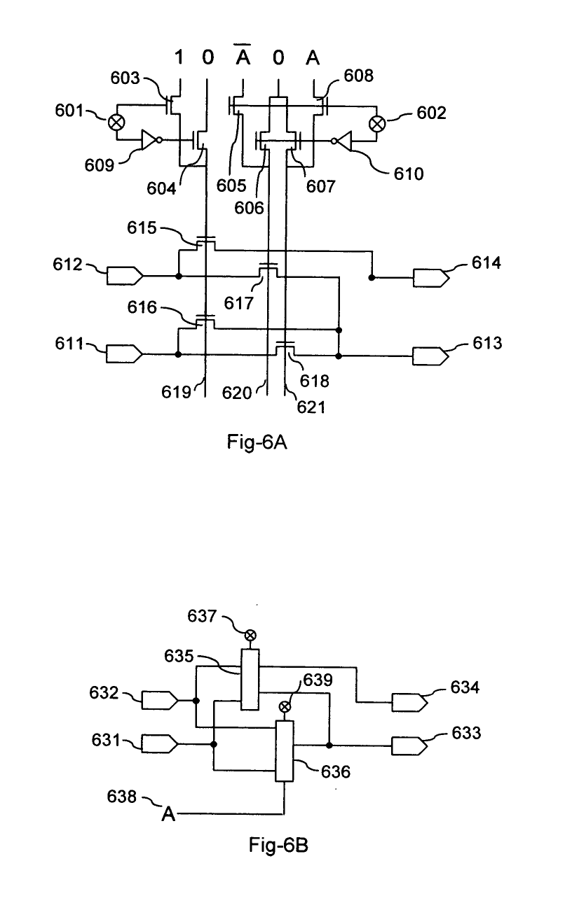

FIG. 6A shows an embodiment of a routing structure, such as circuits 417, 427, 437, 447 shown in FIG. 4A, that couples a physical memory block comprising two nodes to a logical memory domain. In FIG. 6A, nodes 611, 612 are fixed nodes located in the physical memory such as 411, 413, 431, 433 in FIG. 4A. Nodes 613, 614 are located in the logical memory interface such as 416, 426, 436, 446 in FIG. 4A. Even though two nodes 613 and 614 are provided in the logical domain, the user may elect to use one node 613, or both nodes 613 and 614. In the logical domain, nodes 613, 614 are grouped into a plurality of subsets, each subset providing a unique number of nodes between 1 and 2 to the user. In FIG. 6A, two such subsets are formed: a first subset comprising one node 613, and a second subset comprising two nodes 613, 614. In FIG. 6A, the node 614 cannot be used singly in the logical domain. Configuration bits 601, 602 are programmed by the user to make the choice. Bits 601, 602 are similar to circuit 350 in FIG. 3F comprising a logic output either at logic zero or logic one. Inverters 609, 610 provide the means to invert the control signal from the configuration bits. In SRAM, if both outputs are used, these inverters are not required. The configuration memory bits may be further constructed as disclosed in the previous sections in a 3D configuration. While two bits 601, 602 are shown in FIG. 6A, the circuit can be easily modified to use only one bit: then the user must elect either said first subset or said second subset and cannot disable both options. To make the conversion to a single bit, bit 601 & inverter 609 are eliminated, gate 603 is coupled to output of inverter 610, and gate 604 is coupled to output of bit 602.

The routing structure in FIG. 6A, comprises a first routing device comprising pass-gates 615, 616. These pass-gates may be NMOS, PMOS, CMOS or any other programmable switches comprising an ON state and an OFF state, and provide a unique coupling between nodes 611, 613 pair, and 612, 614 pair. The control signal 619 to both gates is a fixed input either at logic zero, or at logic one, selected by the state of the configuration bit 601. In another embodiment, bit 601 output directly couples gates 615 and 616. In both cases, when bit 601 output is at logic one, both gates 615, 616 are ON. When the bit 601 output is at logic zero, both gates 615, 616 are OFF. Thus bit 601 provides a means to activate gates 615, 616 or deactivate gates 615, 616. When the gates are activated, node 611 is coupled to node 613, and node 612 is coupled to node 614. Two nodes in logical domain directly couple to two nodes in the physical domain to READ or WRITE data. No decode is necessary. During this mode bit 602 is programmed to deactivation mode. Similarly, bit 602 provides a means to activate (bit output logic one) or deactivate (bit output logic zero) gates 617, 618. Both bits 601, 602 cannot be set to logical one, while both bits can be set to logical zero. When bit 602 is activated, both nodes 611, 612 are coupled to node 613 via pass-gates 618, 617 respectively. Decoding is now necessary. This coupling scheme is different from the previous coupling scheme. The control signals are generated by an address line A and /A (meaning not A). Thus based on the address value, either node 611 (A=1) or node 612 (A=0) is coupled to node 613. By providing a single logical node 613, and address line A connections to the FPGA fabric, the user can access both physical nodes 611 and 612 in either READ, or WRITE modes. The row-line location is provided in the row address signals.

In one embodiment the configuration bits 601, 602 are constructed in a semiconductor module layer positioned substantially above a semiconductor substrate layer used to construct devices 603-608 and 615-618. This allows a significant area (hence cost) reduction to the routing structure. Devices 609, 610 may be in either of the two module layers. In a second embodiment, the configuration bits further comprises two manufacturing configurations: a first manufacturing configuration comprised of a RAM construction wherein the user is allowed field re-programmability, and a second manufacturing configuration comprised of a ROM construction wherein the user is allowed mask programmability by hard-wiring one of said RAM patterns from the first configuration. In a third embodiment, the configuration bits 601, 602 and inverters 609, 610 output an elevated Vcc level compared to logic Vcc for signal levels at nodes 611-614. Then, pass-gates 603-608 can be constructed as NMOS pass-gates, which consume much lower Si area compared to CMOS pass-gates. It is preferred that pass-gates 615-618 are constructed as CMOS pass-gates to achieve high performance, and transmit full signal levels. Devices 603, 604, 606, 607 can be further constructed as narrow width transistors as they couple fixed voltage levels to control lines and no transient signal levels are encountered.

The circuit shown in FIG. 6A is shown in a block diagram in FIG. 6B. The routing structure in FIG. 6B to couple nodes between physical and logical structures comprises: (i) a first set of 2 nodes 631 and 632; and (ii) a second set of 2 nodes 633 and 634, said nodes arranged in a first subset of only one node 633, and a second subset of two nodes 633 and 634, both said subsets comprising a different number of nodes between 1 and 2; and (iii) two routing devices 635 and 636, each device comprising a unique coupling scheme between the 2 nodes in said first set and a said subset of nodes in the second set, each said routing device further comprising: a configuration bit 637 (or 639) to select or deselect one or both of the routing devices; and a variable number of address signals (none for routing device 635, and one for routing device 636) to selectively couple one node in the first set to one node in the second set. In FIG. 6B, deselect of 635 and 636 isolates the first set of nodes from the second set of nodes; select of 635 couples the first set of nodes to both nodes in the second set; and select of 636 couples the first set node 631 to second set node 633 if address signal 638 is true, and the first set node 632 to second set node 633 if address signal 638 is complement.

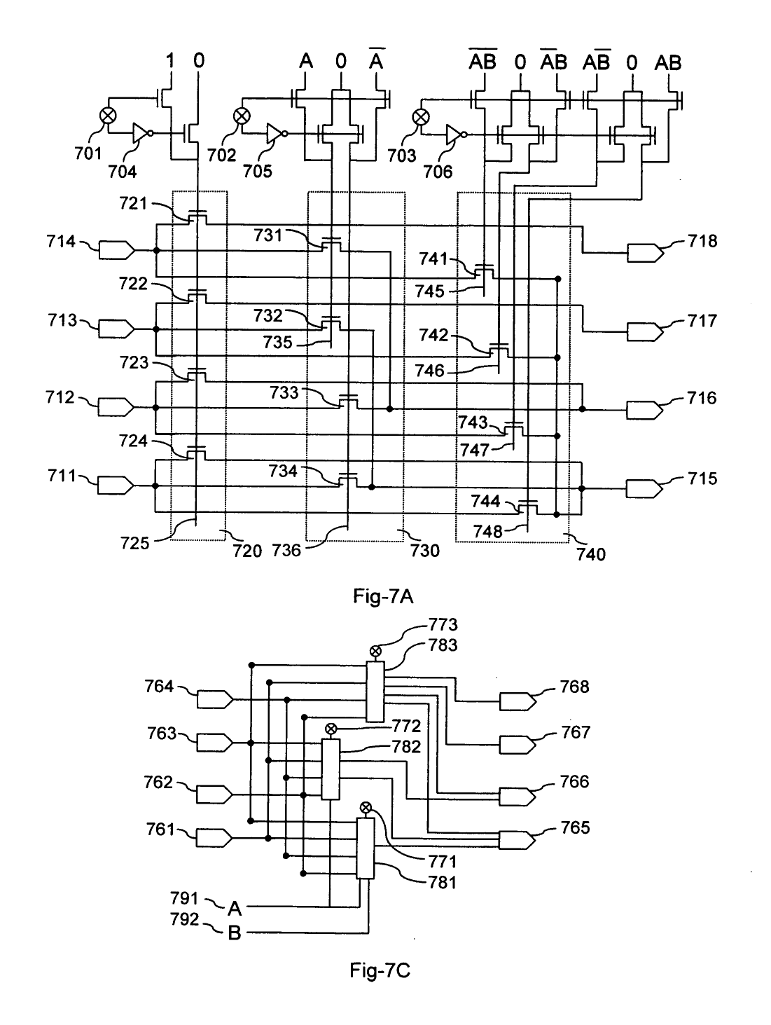

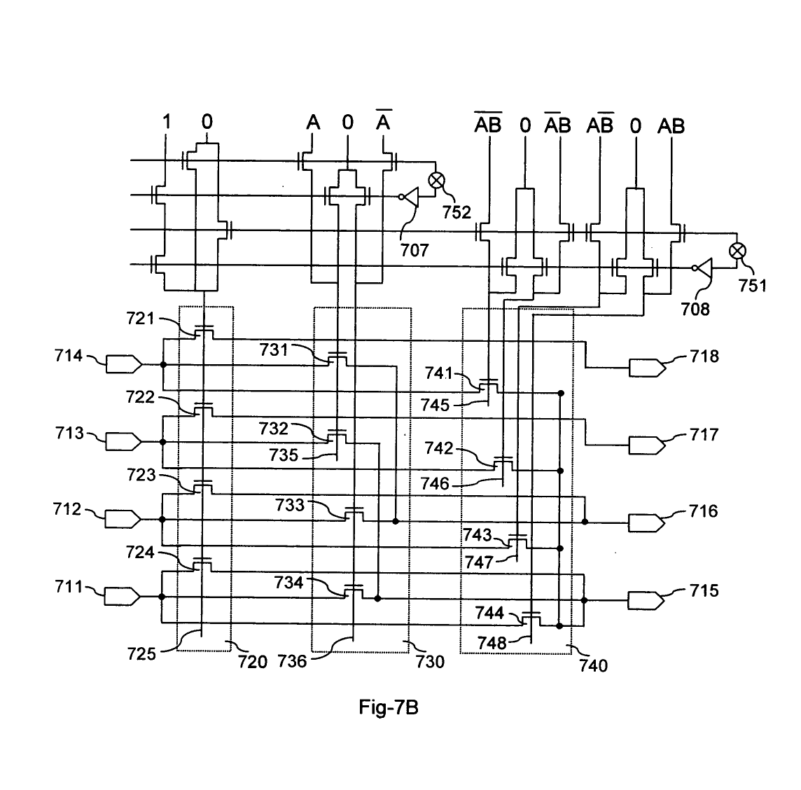

FIG. 7A shows a first embodiment of a routing structure to couple 4-nodes of a physical memory block to logical domain. In this the data width N=4. A first set of nodes in the physical memory comprises 4 nodes 711-714. A second set of nodes in the logical memory comprises 4 nodes 715-718. A plurality of subsets, 3 subsets in the shown embodiment, formed from the 4-nodes in the second set, each subset comprising a unique number of nodes in the range 1 to 4. A first subset comprises one node 715, a second subset comprises two nodes 715, 716 and a third subset comprises 4 nodes 715, 716, 717, 718. These subsets are pre-chosen, and could be easily selected to be any other combination of the 4 nodes in the second set. The routing structure comprises 3 routing devices (720, 730, 740), each routing device coupling the 4 nodes in the first set to a subset of nodes in the second set. Each routing device further comprises 4 coupling devices. Routing device 720 comprises 4 coupling devices 721-724, the coupling devices controlled by control line 725. The coupling device is activated or deactivated by configuration bit 701. For this routing device, the configuration bit 701 can directly generate the control signal 725. Coupling device 720 has no address lines; a fixed input at logic zero or logic one signal level on control line 725 determines the deactivated or activated states respectively of the routing device. A logic one output from bit 701 activates the routing device, coupling nodes 711 to 715, 712 to 716, 713 to 717 and 714 to 718. One node in the first set is coupled to one node in the third subset of the second set. When routing device 720 is deactivated, logic zero on the control line 725 decouples all the nodes in the first set from the subset nodes in the second set. Routing device 730 comprises 4 coupling devices 731-734, the coupling devices controlled by two control lines 735, 736. The coupling device is activated or deactivated by configuration bit 702. The coupling device has one address line A, received in true and complement signal levels. Logic zero or signal A on control line 735 and logic zero or signal /A on control line 736 determine the deactivated or activated states of the coupling devices. A logic one output from bit 702 activates the routing device, coupling nodes 711 to 715, 712 to 716, 713 to 715 and 714 to 716 respectively. Since the address signal A or /A selects which of the two nodes in the first set is coupled to the two nodes in the second set, only one node in the first set is coupled to one node in the second subset of the second set at any given time. When routing device 730 is deactivated, logic zero on the control lines 735, 736 decouples all the nodes in the first set from the subset nodes in the second set. Routing device 740 comprises 4 coupling devices 741-744, the coupling devices controlled by four control lines 745-748. The routing device is activated or deactivated by configuration bit 703. The routing device receives two address lines A & B (four address values). Logic zero or decoded signals AᵢBᵢ on control lines 745-748 determine the deactivated or activated states of the coupling devices. A logic one output from bit 703 activates the routing device, coupling all 4 nodes 711, 712, 713, 714 to 715. Since the address signal /A/B, /AB, A/B, AB select which of the four nodes in the first set is coupled to the one node in the second set, only one node in the first set is coupled to one node in the first subset of the second set at any given time. When routing device 740 is deactivated, logic zero on all control lines 745-748 decouples all the nodes in the first set from the second set.

A two bit adaptation of the routing structure in FIG. 7A is shown in FIG. 7B. As the 3 routing devices in the structure are the same as in FIG. 7A, the device numbering is kept identical. Only how the control signals are generated has changed. In FIG. 7B, when configuration bits 751, 752 are programmed to output logic zero, routing device 720 is activated by a logic one control signal on 725. Routing device 730 and 740 are deactivated with logic zero voltage levels on the control lines 735, 736, 745-748. When bit 752 is set to output 1 and bit 751 is set to output 0; routing devices 720, 740 are deactivated by the bit 751 and bit 752 outputs. Routing device 730 is activated by bit 752 output, and address signal A controls the coupling scheme between first set nodes and the corresponding subset nodes of the second set. When bit 751 is set to output 1 and bit 752 is set to output 0; routing devices 720, 730 are deactivated by the bit 751 and bit 752 outputs. Routing device 740 is activated by bit 751 output, and address signals A, B control the coupling scheme between first set nodes and the corresponding subset nodes of the second set.

The circuit shown in FIG. 7A or 7B is shown in a block diagram in FIG. 7C. The programmable routing structure in FIG. 7C to couple nodes between physical and logical domains, comprises: N=4 (761-764) nodes in a physical domain, where N is an integer greater than one; and N=4 (765-768) nodes in a logical domain, said nodes arranged in a plurality of sets, each said set comprising a different number of nodes between one and N (first set of 1 node 765, second set of 2 nodes 765-766, third set of 4 nodes 765-768); and a plurality of routing devices (781-783), each device comprising a unique coupling scheme between the N=4 nodes (761-764) in said physical domain and the nodes of a said logical domain set (node 765, or nodes 765-766, or nodes 765-768), each said routing device further comprising: a configuration element (one of 771-773) to activate or deactivate the routing device; and a fixed input (logic zero or logic one) or an address signal (791 or 792 or both) to selectively couple the physical domain set nodes to logical domain N=4 nodes. The routing devices (781-783) comprises a variable number of address signals (zero for routing device 783, one for routing device 782 and two for routing device 781) to selectively couple one node in the physical domain to one node in the logical domain. The routing structure in FIG. 7C further comprises a first routing device 783 comprised of zero address signals; and a second routing device 782 comprised of a first address signal 791; and a third routing device 781 comprised of said first address signal 791 and another address signal 792. In the structure of FIG. 7C, the configurable element 771 provides a means to couple a logic zero or the four address values to the routing structure 781. A detail construction of routing structures 771, 772 and 773 are shown in FIG. 7A/7B as 720, 730 and 740 respectively. These configuration elements 771-773 comprises a memory element selected from one of: fuse links, anti-fuse capacitors, SRAM cells, DRAM cells, metal optional links, EPROM cells, EEPROM cells, flash cells, ferro-electric elements, Carbon nano-tubes, optical elements, electro-chemical elements, resistance-modulating elements and magnetic elements.

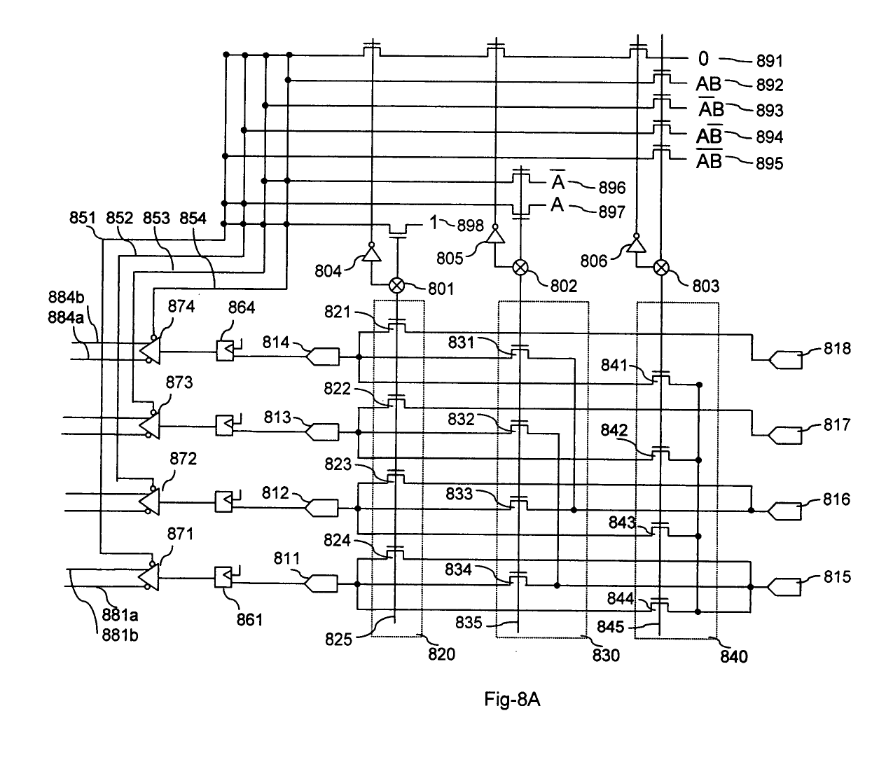

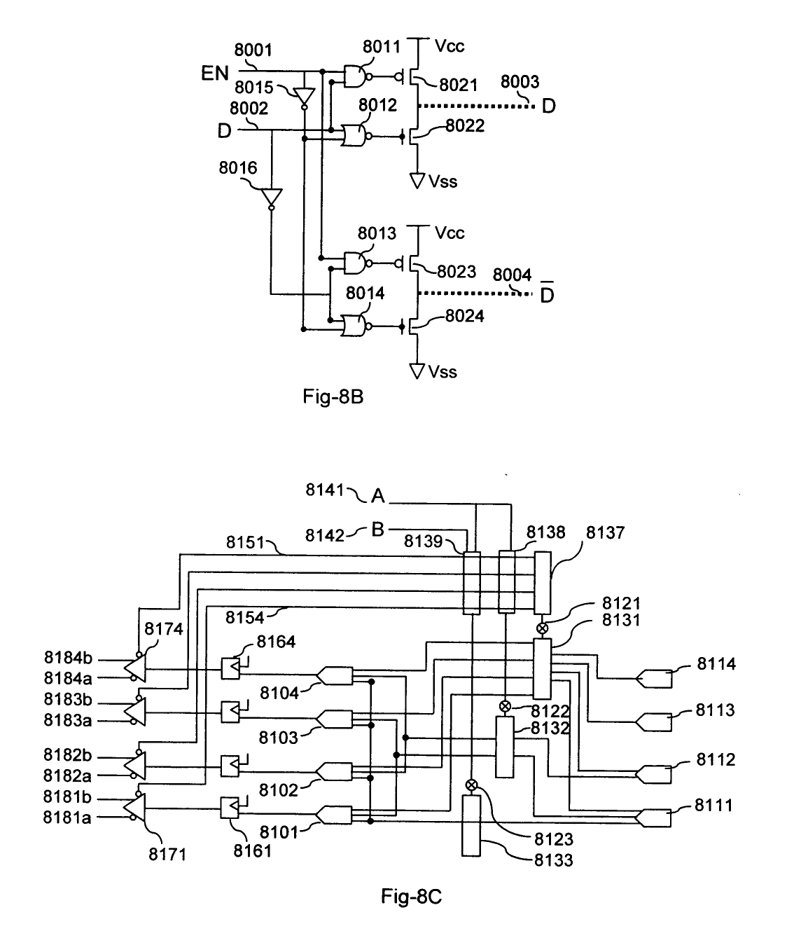

Another routing structure according to the current invention is presented in FIG. 8A-8C. FIG. 8A shows the routing structure circuits, FIG. 8B shows the tri-state drivers used in the invention, and FIG. 8C shows the block diagram for FIG. 8A. In FIG. 8A, a first set of nodes in the physical memory comprises nodes 881-884, and a second set of nodes in the logical memory comprises nodes 815-818. Nodes 811-814 are intermediate nodes coupled to physical nodes 881-884. The second set further comprises a plurality of subset nodes. In the embodiment shown, three subsets are shown: a first subset comprising node 815, second subset comprising nodes 815-816, and a third subset comprising nodes 815-818. A separate routing device 820, 830, 840 couples a said subset of nodes in the second set to the nodes in the first set. Routing device 840 comprises four coupling devices 841-844 to couple the first subset node 815 to all four nodes 811-814, control signal 845 activating or deactivating said coupling. Routing device 830 comprises four coupling devices 831-834 to couple the second subset nodes 815 to 811, 813 and 816 to 812, 814 in a pair-wise fashion, control signal 835 activating or deactivating said coupling. Routing device 820 comprises four coupling devices 821-824 to couple the third subset nodes 815 to 811, 816 to 812, 817 to 813, and 818 to 814, control signal 825 activating or deactivating said coupling. Each of the coupling devices 821-824, 831-834, 841-844 comprise an ON state that couples two nodes, and an OFF state that decouples two nodes. These may comprise NMOS, PMOS or CMOS transistors. They may comprise resistance-modulating elements. They are configurable: either by a control signal as shown in FIG. 8A or by a programming technique that offers a state change between ON and OFF states. Each of the routing devices 820, 830, 840 comprises a unique coupling scheme and is activated or deactivated by a control signal generated by the configuration bits 801, 802, 803 respectively. A logic one output from the configuration bit activates the routing device, and a logic zero from the configuration bit deactivates the routing device. In one embodiment, the first set of nodes 811-814 are coupled to registers 861-864 individually as shown. These registers may be configurable, and they may further posses register-by-pass circuitry to enable asynchronous applications. The registers may also comprise clock, set, reset and other types of control circuitry. These registers may be replaced by any storage elements such as latches and Flip-Flops. In another embodiment, the first set of nodes 811-814 are directly coupled to drivers 871-874 individually. These drivers can be tri-stated, they provide true and compliment buffered signals at the output. Such circuits are disclosed in application Ser. No. 10/691,013 now U.S. Pat. No. ______, filed Oct. 23, 2003 and lists as inventor Mr. R. U. Madurawe, the contents of which are incorporated herein by reference. Each of the drivers 871-874 comprises a unique enable signal 851-854 which is further configured to provide a specific control signal by the configuration bits 801-803. In the embodiment shown, each driver has an input and generates two outputs, one output having a buffered signal with the same input polarity, and a second output having a buffered signal of opposite polarity to input. In other embodiments, only one output may be generated by the driver. Four specific programming conditions for enable signals in FIG. 8A are discussed next.

(i) All 3 bits 801-803 output zero: None of the 3 routing devices 820, 830, 840 is selected. Signal 891 at logic zero voltage is coupled to all four enable signals 851-854. Signals 892-898 are isolated from signals 881-884 by the configuration bits. When logic zero is coupled to the enable signals 851-854 of drivers 871-874, they are disabled and nodes 881a-884b are all tri-stated (floating, not driven) regardless of the input states at nodes 811-814. Furthermore nodes 815-818 are isolated from nodes 811-814 as well, as all 4 routing devices are deactivated. Thus the external logic memory states on nodes 815-818 are not driven in to the physical memory array nodes 881-884; logical and physical memory arrays are isolated from one another.

(ii) Bit 801 outputs 1, bits 802, 803 outputs zero: Routing device 820 is activated, while routing devices 830, 840 are deactivated. Signal 898 at logic one voltage is coupled to all four enable signals 851-854. Signals 891-897 are isolated from signals 851-854. When logic one is coupled to the driver-enable signals, the drivers are activated. Drivers 871-874 selectively drive data on nodes 815-818 in to the physical memory array via routing device 820 to nodes 881-884. Both true and opposite polarity signals are generated by the drivers. 881a, 882a, 883a, 884a show opposite polarity buffered signals, while 881b, 882b, 883b, 884b show the true polarity buffered signals driven into the physical memory array. The routing device 820 provides a single node to single node coupling. Thus each external logical node couples to one internal physical node.

(iii) Bit 802 outputs 1, bits 801, 803 outputs zero: Routing device 830 is activated, while routing devices 820, 840 are deactivated. Signal 896 at logic /A is coupled to enable signals 853-854, and signal 897 at logic A is coupled to enable signals 851-852. Signals 891-895 and 898 are isolated from signals 851-854. The routing device 830 couples a single logical node to a pair of physical nodes. When logic A and /A are coupled to the driver-enable signals, the drivers are activated by the control signal in a pair fashion. Drivers 871-872 drive data on nodes 815-816 when A=1, and drivers 873-874 drive data on nodes 815-816 when A=0. Thus an external logical node couples to one internal physical node based on the A address value.

(iv) Bit 803 outputs 1, bits 801, 802 outputs zero: Routing device 840 is activated, while routing devices 820, 830 are deactivated. Signal 892 at logic AB is coupled to enable signal 854, signal 893 at logic /AB is coupled to enable signal 853, signal 894 at logic A/B is coupled to enable signal 852, and signal 895 at logic IA/B is coupled to enable signal 851. Signals 891, 896-898 are isolated from signals 851-854. The routing device 840 couples a single logical node to all four physical nodes. The drivers are activated by the control signals AᵢBᵢ generated by the address lines. Drivers 871-874 drive data on node 815 based on this address value, one driver at a time activated by a particular AᵢBᵢ=1 value. Thus the external logical node couples to one internal physical node based on the AᵢBᵢ address values.

Additional control logic signals can be easily coupled to the enable signals 851-854 for all drivers 871-874 in FIG. 8A. In a preferred embodiment, a control logic signal CON (not shown) is logically-AND with each enable signal: CON AND 851, CON AND 852, CON AND 853, CON AND 854. These new signals are then provided to the enable input of each driver. This allows the CON signal to tri-state every driver when exerted, thus avoiding the write and read functions to corrupt data at a given address location in a conflict situation.

Each of the driver circuits (or driver devices) 871-874 comprises tri-state or data (D) and not-data (/D) output capabilities. One embodiment of such a circuit is shown in FIG. 8B. The driver device in FIG. 8B comprises two inputs; a data input 8002 and an enable input 8001. It comprises two outputs; a buffered data out 8003, and a buffered compliment data (/data) out 8004. Each output is generated by a pull-up device (8021 or 8023) and a pull-down device (8022 or 8024). The driver device comprises two states: a tri-state, and a data-state. During tri-state (EN=0), the driver is inactive, both said data and /data outputs are not driven and floating. This is achieved by deactivating both pull-up and pull-down devices that generate the data and /data outputs. During the data-state (EN=1), output 8003 provides a buffered signal of the input 8002, and output 8004 provides a buffered compliment signal of the input 8002. NAND gates 8011, 8013 and NOR gates 8012, 8014 provides the necessary logic to generate the tri-state signals to the two buffer stages (one stage 8021, 8022), (other stage 8023, 8024). When 8001 signal EN=0, both 8011, 8013 output 1 no matter what D input is, and PMOS 8021, 8023 are both off. When EN=0, inverter 8015 provides a 1 input to both NOR gates 8012, 8014 which in turn output 0 regardless of D input state, thus NMOS 8022, 8024 are both off. Nodes 8003 and 8004 are isolated or in tri-state mode with input 8002 cut-off from the two outputs 8003, 8004. When EN=1, the NAND and NOR gates respond to input D on 8002. D=1 activates PMOS 8021 and NMOS 8024 to provide 8003=buffered 1, 8004=buffered 0. Similarly, D=0 activates NMOS 8022 and PMOS 8023 to provide 8003=buffered 0, 8004=buffered 1.

A block diagram for the routing structure in FIG. 8A is shown in FIG. 8C. The programmable routing structure in FIG. 8C to couple nodes between logical and physical domains, comprises: N=4 nodes (8111-8114) in a logical domain, said nodes arranged in M=3 sets, where N and M are integers greater than one, each said set comprising a different number of nodes between one and N (first set of one node 8111, a second set of 2 nodes 8111-8112, a third set of 4 nodes 8111-8114); and N=4 nodes (8181-8184) in a physical domain, each node coupled to an output of a driver (one of 8171-8174), each said driver further comprising: an input (one of 8101-8104), and an enable signal (one of 8151-8154) comprising two signal levels (logic zero and logic one), wherein a first level (logic zero) tri-states said output and a second level (logic one) generates an output from said input; and M=3 routing devices (8131-8133), each routing device comprising: a plurality of coupling devices to uniquely couple the nodes of a said logical domain set (first set 8111, second set 8111-8112 or third set 8111-8114) to the N inputs (8101-8104) of said drivers; and a configuration bit (one of 8121-8123) to activate or deactivate the plurality of coupling devices (within 8131-8133); wherein, said configuration bits further couple a fixed input (logic zero or logic one) or an address signal (8141 or 8142 or both) to each of said enable signals to selectively couple logical domain nodes to physical domain nodes. In FIG. 8C, configuration element 8121 provides a means to couple or decouple a fixed one input to all said enable signals 8151-8154; Configuration element 8122 provides a means to couple or decouple an address signal 8141 comprising two address values, wherein a first portion of enable signals (8151-8152) couple to a first address value, and a second portion of enable signals (8153-8154) couple to a second address value; Configuration element 8123 provides a means to couple or decouple Q=2 address signals comprising P=2^{Q}=4 address values, wherein: a first portion of enable signals (8151) couple to a first address value; and a second portion of enable signals (8152) couple to a second address value; and a P^{th} portion of enable signals (8154) couple to a P^{th} address value; where Q is an integer value greater than one.

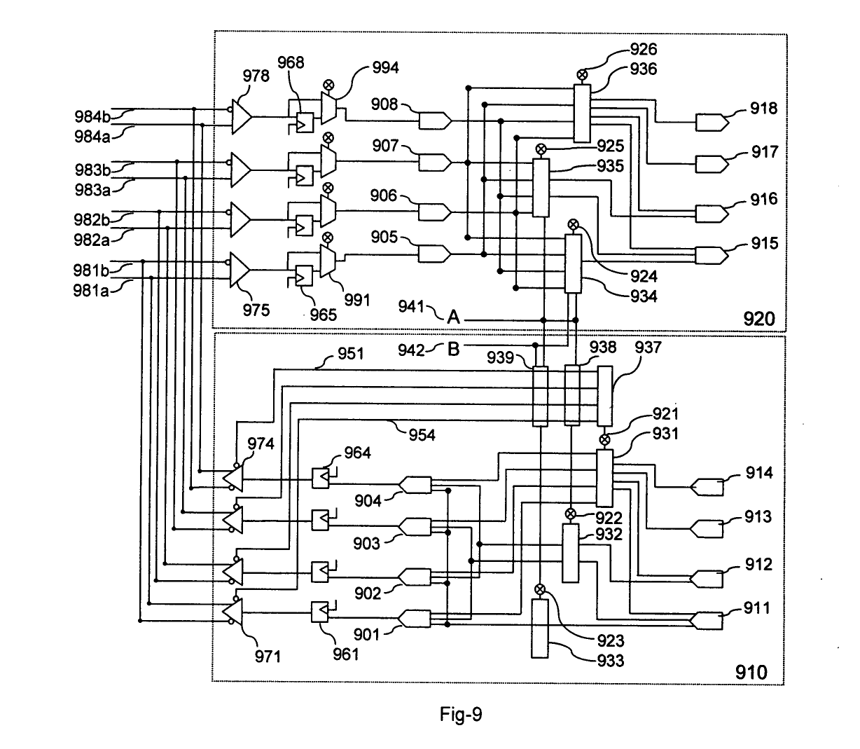

The construction of READ and WRITE functions at a single port (Port-A or Port-B) is shown in FIG. 9 for a 4-node (N=4) physical memory block. An N>4 node physical memory block can be easily constructed analogously to what is shown in FIG. 9 by one familiar in the art. Each port has a unique set of column line pairs 981-984 in the Physical memory domain. Two such pairs (981a, 981b) & (981c, 981d—not shown) are denoted 402 in FIG. 4A for the bit 403, and further as (471, 472) and (461, 462) in FIG. 4B. The READ function is shown in circuit block 920, while the WRITE function is shown in circuit block 910. Column lines 981c, 981d are generated by the second port, not shown in FIG. 9.

The READ function is described briefly first. When one ROW line in the physical memory block is selected by the address-lines (such as lines 420 for port 410 in FIG. 4A), 4-bits in the physical memory block are coupled to column lines 981-984, each physical memory bit driving DATA and /DATA in a pair of column lines such as 981a, 981b. These are detected by sense devices 975-978 and latched to storage units 965-968. Storage units are provided with clock, clock enable, set, reset and other control inputs for synchronous operations. To facilitate asynchronous operations, storage by-pass and programmable selection circuits 991-994 are provided. The user can program devices 991-994 to select synchronous or asynchronous READ modes. The storage units can be simple latches, or registers, or flip-flops and one familiar in the art may construct many other forms of such elements. The outputs from the devices 991-994 form a first set of nodes 905-908, these nodes providing data values located in the physical memory at a specified address location. A FIG. 7C routing structure couples the first set of nodes to a second set of logical nodes 915-918. The user may elect one of three subsets to connect the physical memory to a READ function at the port: a first subset comprising one node 915 (×1 mode), a second subset comprising 2 nodes 915-916 (×2 mode), and a third subset comprising 4 nodes 915-918 (×4 mode). These subsets are chosen for illustrative purposes and should not be taken in a limiting sense. The user is provided address lines 941 (A), 942 (B) to decode the READ data: if ×1 mode is selected both address lines are required, if ×2 mode is selected only address line 941 is needed, and if ×4 mode is selected no address lines are required. Similarly based on the READ mode, only the required logical nodes need to be connected: node 915 for ×1 mode, nodes 915-916 for ×2 mode, and all nodes 915-918 for ×4 mode. The READ function shown in circuit 920 provides the capability to couple physical memory received in column lines 981-984 to a configurable subset of logical nodes 915-918.

The WRITE function shown in 910 is described next. A set of nodes 911-914 (different from the logical READ nodes 915-918) are provided as logical WRITE nodes to the user. These logical WRITE nodes are coupled to the column lines 981-984 in the physical memory using a routing structure as described in FIG. 8A. The user may elect one of three subsets in the WRITE function to connect to the physical memory: a first subset comprising one node 911 (×1 mode), a second subset comprising 2 nodes 911-912 (×2 mode), and a third subset comprising 4 nodes 911-914 (×4 mode). These subsets are chosen for illustrative purposes and should not be taken in a limiting sense. The user is provided address lines 941 (A), 942 (B) to select the WRITE decode: if ×1 mode is selected both address lines are required, if ×2 mode is selected only address line 941 is needed, and if ×4 mode is selected no address lines are required. In a preferred embodiment, the READ and WRITE functions share common address lines as shown in FIG. 9. In other embodiments, these address lines may differ, and two sets of address lines may be provided to the user, or a partial set of address lines may be made common between the two functions. Based on the WRITE mode, only the required logical nodes need to be connected: node 911 for ×1 mode, nodes 911-912 for ×2 mode, and all nodes 911-914 for ×4 mode. In the routing structure 910, for the three WRITE modes offered, three programmable routing devices 931-933 are offered. None or one of them can be selected by the user-configuration bits 921-923 provide the configurability. In a preferred embodiment, these configuration bits 921-923 are different from the READ configuration bits 924-926. Then, the READ mode and the WRITE mode can be different from each other. For example, the READ mode may be ×2, while the WRITE mode may be ×4 at the same port in the multi-port memory structure. In a second embodiment, the configuration bits 921-923 are identical to the READ configuration bits 926-924 respectively. Then, the READ mode and the WRITE mode are identical to one another. For example, if READ mode is selected to be ×2, the WRITE mode is also ×2 at the same port in the multi-port memory structure. The configuration bits can be arranged such that the READ function and the WRITE function has a fixed mode non-identical selection. For example, if configuration bit 921 is made common with 925, the READ mode ×2 is coupled to WRITE mode ×4 mode. As discussed in FIG. 8A, the selection of WRITE mode automatically selects the necessary address scheme utilizing 0 to 2 address lines from A, B via selection circuits 937-939 to generate enable signals 951-954. Only drivers 971-974 selected by the enable signals 952-954 provide the WRITE feature into physical memory array via column lines 981-984. Once the appropriate data is provided to column lines, the row address lines in the physical array such as 440 in FIG. 4A for WRITE mode is asserted, and the data values are stored in individual cells thus selected. The WRITE function shown in circuit 920 provides the capability to couple logical memory data received in a configurable subset of logical nodes 911-914 to column lines 981-984 in the physical memory, to be stored in individual cells within the said physical array.

A programmable routing structure in FIG. 9 to couple physical nodes to logical read and write domains at a single port in a multi-port embedded memory array, comprises: a plurality of physical domain nodes (981-984); and a plurality of logical read domain nodes (915-918) arranged in a plurality of sets, each set comprising a different number of nodes (first set of 1 node 915, second set of 2 nodes 915-916, third set of 4 nodes 915-918); and a plurality of logical write domain nodes (911-914) arranged in a plurality of sets, each set comprising a different number of nodes (first set of 1 node 911, second set of 2 nodes 911-912, third set of 4 nodes 911-914); and a plurality of routing devices (931-936), each said device to couple nodes in a set of said logical read and write domains to the physical domain nodes, wherein: a single read domain set and a single write domain set comprising the same or a different number of nodes is selected by one or more configuration elements (921-926); and a common address signal (941 or 942 or both) selectively couple the nodes in said selected logical read and write domain sets to the physical domain nodes. FIG. 9 further comprises: N=4 nodes in said physical domain, where N is an integer greater than one; and N=4 nodes in said logical read domain, each said sets comprising nodes between one and N; and N nodes in said logical write domain, each said sets comprising nodes between one and N; and each said routing device (one of 931-936) further comprising a unique coupling scheme between the N nodes in said physical domain and the nodes of a said set in logical read and write domains, wherein said selection of read domain set and write domain set further comprises activating or deactivating the corresponding routing device by the one or more configuration elements (921-926).

The routing structure in FIG. 9 provide READ and WRITE functions for a single port in a multi-port physical memory array, wherein the logical READ data width and the logical WRITE data width can be independently configured, and wherein the READ and WRITE functions share common address lines. The structure in FIG. 9 further comprises a READ function, wherein a plurality of routing devices couple a set of nodes from the physical domain to a plurality of subset nodes in a logical domain, wherein a configuration bit activates or deactivates the routing device, and wherein address signals selectively couple a single node in the physical domain to a single node in the logical domain. The structure in FIG. 9 further comprises a WRITE function, wherein a plurality of routing devices couple a plurality of subset nodes from a logical domain to inputs of a set of drivers, wherein a configuration generates an enable signal to selectively couple a single node in the logical domain to a single pair of column lines in the physical memory array.

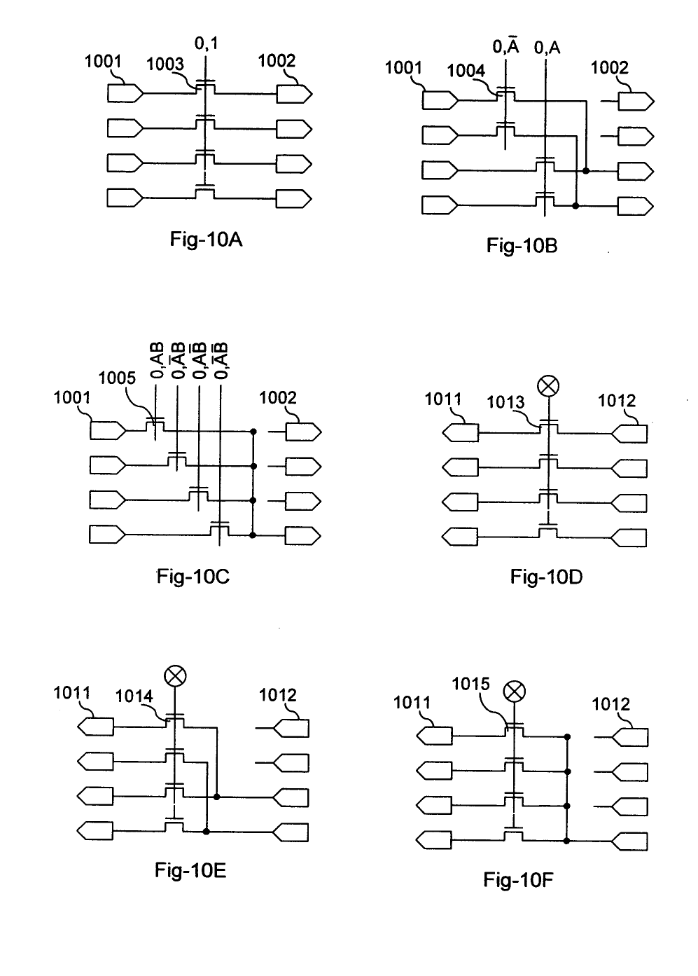

FIG. 10 shows the routing devices 931-936 deployed in FIG. 9. For the READ routing structure 920 in FIG. 9, routing device 934 is FIG. 10C, 935 is FIG. 10B and 936 is FIG. 10A. Each of FIGS. 10A-10C comprises a unique coupling scheme. They all couple a first set of nodes 1001 to a plurality of subset nodes in a second set of nodes 1002. They all comprise a plurality of coupling devices such as 1003, 1004, 1004 to complete the coupling scheme. FIG. 10A couples all nodes in first set to all nodes in second set, a control signal at logic zero or logic one deactivates or activates the coupling. No address signals are required. FIG. 10B couples all nodes in the first set to half the nodes in the second set. Two control signals are provided to control coupling. When both control signals are at logic zero the routing device is deactivated. When address signals A and /A are coupled to control signals, FIG. 10A is activated. Then signal level on A selectively couples a pair of nodes in the first set to the two nodes in the second set. FIG. 10C couples all nodes in the first set to one node in the second set. Four control signals are provided: a logic level on all four control signals deactivates the coupling. Decoded signal levels on the two address lines A & B select one node in first set to couple to the node in second set. For the WRITE routing structure 910 in FIG. 9, routing device 931 is FIG. 10D, 932 is FIG. 10E and 933 is FIG. 10F. Each of FIGS. 10D-10F comprises a unique coupling scheme. Each routing device comprises a plurality of coupling devices 1013, 1014, 1015. They all couple a subset of nodes from a set of logical nodes 1012 to a set of nodes in a first set 1011. The subset comprises 1 to N=4 nodes. In a preferred embodiment, each subset further comprises a different number of nodes. A configuration bit activates or deactivates each routing device: a zero output deactivating and a one output activating the device. FIG. 10D couples all nodes in first logical subset to all nodes in first set, a configuration bit output at logic zero or logic one deactivates or activates the coupling. No address signals are required. FIG. 10E couples two nodes in a second logical subset to all nodes in the first set in a pair-fashion, a configuration bit output at logic zero or logic one deactivates or activates the coupling. A single node in the logical domain couples to two nodes in the first set and no address lines are required. A single address lines control drivers that drive these data signals into the physical memory array, two bits at a time. FIG. 10E couples a single logical subset node to all nodes in the first set. The configuration bit activates or deactivates the coupling. When coupled, the single logical node couples to all four nodes in the first set and no address lines are required. Two address lines control drivers that drive these data signals into the physical memory array, one bit at a time. In a first embodiment, the routing devices in FIG. 10A to 10C comprise a pass-gate constructed on a silicon substrate layer, and a configuration element constructed in a semiconductor thin film layer positioned substantially above the silicon substrate layer. In a second embodiment, the routing devices in FIG. 10A to 10C comprise a switch to couple two nodes and a configurable element to program the switch, wherein the switch and the configurable element are located above a gate-poly layer deposited on a substrate. In a third embodiment, the routing devices in FIG. 10A-10C comprise a configurable element to configure a coupling device, the configurable element comprising two manufacturing configurations: a first configuration comprises a RAM element, and a second configuration comprises a ROM element in lieu of the RAM element to identically program the coupling device.

As disclosed, 3-dimentional thin-film transistor module integration allows a portion of configuration circuits and/or a portion of embedded memory blocks to be built vertically above logic circuits. These circuits contain static memory elements that control pass-gates constructed in substrate Silicon. The TFT layers are fabricated above a metal layer in a removable module, facilitating a novel method to remove completely from the process. Configuration circuits are mapped to a hard-wire metal links to provide the identical functionality in the latter. Once the programming pattern is finalized with the thin-film module, and the device is tested and verified for performance, the TFT cells can be eliminated by hard-wire connections. Such conversions allow the user a lower cost and more reliable end product. These products offer an enormous advantage in lowering NRE costs and improving Time to Solution (TTS) in the ASIC design methodology in the industry. Although an illustrative embodiment of the present invention, and various modifications thereof, have been described in detail herein with reference to the accompanying drawings, it is to be understood that the invention is not limited to this precise embodiment and the described modifications, and that various changes and further modifications may be effected therein by one skilled in the art without departing from the scope or spirit of the invention as defined in the appended claims.

What is claimed is:

1. A programmable routing structure to couple nodes between physical and logical domains, comprising:
N nodes in a physical domain, where N is an integer greater than one; and
N nodes in a logical domain, said nodes arranged in a plurality of sets, each said set comprising a different number of nodes between one and N; and
a plurality of routing devices, each device comprising a unique coupling scheme between the N nodes in said physical domain and the nodes of a said logical domain set, each said routing device further comprising:
a configuration element to activate or deactivate the routing device; and
a fixed input or an address signal to selectively couple the physical domain set nodes to logical domain N nodes.

2. The structure of claim 1, wherein said configuration element further comprises a volatile or a non-volatile memory element.

3. The structure of claim 1, wherein the routing device comprises a pass-gate device, said pass-gate device further comprising one of: NMOS transistor, PMOS transistor, CMOS transistor pair, thin-film transistor, electro-chemical cell, carbon nano-tube, resistance-modulating cell, and any other configurable coupling element.

4. The structure of claim 1, wherein a said routing device or a said configuration element comprises a configurable element located substantially above a substrate layer.

5. The structure of claim 1, wherein a said configuration element provides a means to couple a fixed zero input or a fixed one input to a said routing device.

6. The structure of claim 1, wherein a said configuration element provides a means to couple a zero input or an address signal comprising two address values to a said routing device.

7. The structure of claim 1, wherein a said configuration element provides a means to couple a zero input or M address signals comprising 2^{M} address values to a said routing device, where M is an integer value greater than zero.

8. The structure of claim 1, wherein said configuration element comprises a memory element selected from one of: fuse links, anti-fuse capacitors, SRAM cells, DRAM cells, metal optional links, EPROM cells, EEPROM cells, flash cells, ferro-electric elements, optical elements, electro-chemical elements, resistance-modulating elements and magnetic elements.

9. A programmable routing structure to couple nodes between logical and physical domains, comprising:
N nodes in a logical domain, said nodes arranged in M sets, where N and M are integers greater than one, each said set comprising a different number of nodes between one and N; and
N nodes in a physical domain, each node coupled to an output of a driver, each said driver further comprising:
an input, and an enable signal comprising two signal levels, wherein a first level tri-states said output and a second level generates an output from said input; and
M routing devices, each routing device comprising:
a plurality of coupling devices to uniquely couple the nodes of a said logical domain set to the N inputs of said drivers; and
a configuration bit to activate or deactivate the plurality of coupling devices;
wherein, said configuration bits further couple a fixed input or an address signal to each of said enable signals to selectively couple logical domain nodes to physical domain nodes.

10. The structure of claim 9, wherein said configuration element further comprises a volatile or a non-volatile memory element.

11. The structure of claim 9, wherein the coupling device further comprises one of: NMOS transistor, PMOS transistor, CMOS transistor pair, thin-film transistor, electro-chemical cell, carbon nano-tube, resistance-modulating cell, and any other configurable coupling element.

12. The structure of claim 9, wherein a said coupling device or a said configuration element comprises a configurable element located substantially above a substrate layer.

13. The structure of claim 9, wherein a said configuration element provides a means to couple or decouple a fixed one input to all said enable signals.

14. The structure of claim 9, wherein a said configuration element provides a means to couple or decouple an address signal comprising two address values, wherein a first portion of enable signals couple to a first address value, and a second portion of enable signals couple to a second address value.

15. The structure of claim 9, wherein a said configuration element provides a means to couple or decouple Q address signals comprising P=2^{Q} address values, wherein:
a first portion of enable signals couple to a first address value; and
a second portion of enable signals couple to a second address value; and
a P^{th} portion of enable signals couple to a P^{th} address value; and
Q is an integer value greater than one.

16. The structure of claim 9, wherein said configuration element comprises a memory element selected from one of: fuse links, anti-fuse capacitors, SRAM cells, DRAM cells, metal optional links, EPROM cells, EEPROM cells, flash cells, ferro-electric elements, optical elements, electro-chemical elements, resistance-modulating elements and magnetic elements.

17. A programmable routing structure to couple physical nodes to logical read and write domains at a single port in a multi-port embedded memory array, comprising:
a plurality of physical domain nodes; and
a plurality of logical read domain nodes arranged in a plurality of sets, each set comprising a different number of nodes; and
a plurality of logical write domain nodes arranged in a plurality of sets, each set comprising a different number of nodes; and
a plurality of routing devices, each said device to couple nodes in a set of said logical read and write domains to the physical domain nodes, wherein:
a single read domain set and a single write domain set comprising the same or a different number of nodes is selected by one or more configuration elements; and
a common address signal selectively couple the nodes in said selected logical read and write domain sets to the physical domain nodes.

18. The structure of claim 17, further comprising:
N nodes in said physical domain, where N is an integer greater than one; and
N nodes in said logical read domain, each said sets comprising nodes between one and N; and
N nodes in said logical write domain, each said sets comprising nodes between one and N; and
each said routing device further comprising a unique coupling scheme between the N nodes in said physical domain and the nodes of a said set in logical read and write domains, wherein said selection of read domain set and write domain set further comprises activating or deactivating the corresponding routing device by the one or more configuration elements.

19. The structure of claim 17, wherein a said routing device to couple the nodes in the physical domain to a set of nodes in the logical read domain further comprises one or more control signals, wherein a control signal is generated by a fixed input or said address signal.

20. The structure of claim 17, further comprising a plurality of driver devices, wherein each driver device further comprises:
an output coupled to a node in the physical domain; and
an input coupled to a write domain node that further couples to routing devices that couple the N nodes in the physical domain to the plurality of sets in the logical write domain; and
an enable signal, said enable signal generated by a fixed input or said address signal.
